(19) United States
(12) Patent Application Publication
(10) Pub. No.: US 2026/0082947 A1
(43) Pub. Date: Mar. 19, 2026

(54) SEMICONDUCTOR PACKAGE AND METHOD OF FABRICATING THE SAME

(71) Applicant: Taiwan Semiconductor Manufacturing Company, Ltd., Hsinchu (TW)

(72) Inventors: Sheng-An Kuo, Hsinchu (TW); Chen-Sheng Lin, Taoyuan City (TW); Min-Chien Hsiao, Taichung City (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/890,688

(22) Filed: Sep. 19, 2024

(51) Int. Cl. H01L 23/538; H01L 23/00; H01L 23/31; H01L 23/48; H01L 25/00; H01L 25/10

(52) U.S. Cl. CPC H10W 70/611; H10W 70/685; H10W 90/00; H10W 20/20; H10W 70/60; H10W 74/111; H10W 80/312; H10W 80/327; H10W 90/10; H10W 90/794

(57) ABSTRACT

A semiconductor package includes a plurality of first semiconductor dies, a plurality of first bonding pads, a bridge layer, a plurality of second bonding pads and a plurality of second semiconductor dies. The first bonding pads are disposed on the first semiconductor dies. The bridge layer is disposed on the first bonding pads, wherein the bridge layer is electrically connected to the first semiconductor dies through the first bonding pads. The second bonding pads are disposed on the bridge layer, wherein the second bonding pads are electrically connected to the first bonding pads through the bridge layer. The second semiconductor dies are disposed on and electrically connected to the second bonding pads, wherein an active surface of the first semiconductor dies is facing an active surface of the second semiconductor dies.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 12 are schematic sectional views of various stages in a method of fabricating a semiconductor package according to some exemplary embodiments of the present disclosure.

FIG. 13 is a schematic sectional view of a semiconductor package according to some exemplary embodiments of the present disclosure.

FIG. 14 is a schematic sectional view of a semiconductor package according to some other exemplary embodiments of the present disclosure.

FIG. 15 is a schematic sectional view of a semiconductor package according to some other exemplary embodiments of the present disclosure.

FIG. 16 is a schematic sectional view of a semiconductor package according to some other exemplary embodiments of the present disclosure.

FIG. 17 to FIG. 25 are schematic sectional views of various stages in a method of fabricating a semiconductor package according to some other exemplary embodiments of the present disclosure.

FIG. 26 is a schematic sectional view of a semiconductor package according to some other exemplary embodiments of the present disclosure.

FIG. 27 is a schematic sectional view of a semiconductor package according to some other exemplary embodiments of the present disclosure.

FIG. 28 is a schematic sectional view of a semiconductor package according to some other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor package is formed with a plurality of first semiconductor dies and a plurality of second semiconductor dies, whereby a bridge layer is provided for multiple interconnecting selection between the first and second semiconductor dies. The arrangement of the bridge layer allows for additional paths for signal communication, which can be used for super powerful data processing.

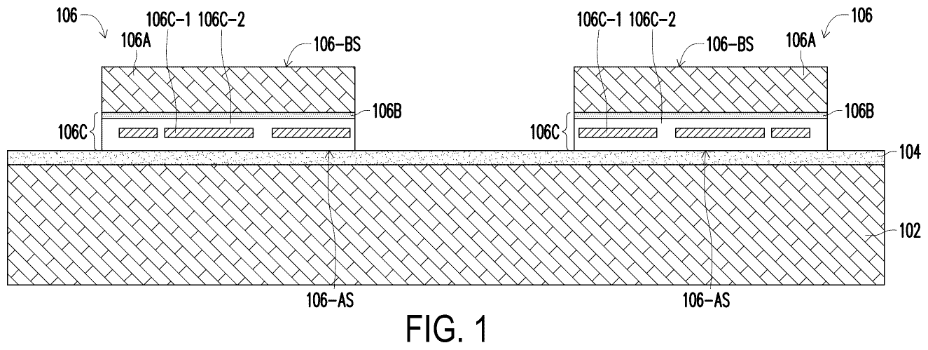

FIG. 1 to FIG. 12 are schematic sectional views of various stages in a method of fabricating a semiconductor package according to some exemplary embodiments of the present disclosure. Referring to FIG. 1, a first carrier 102 is provided. In some embodiments, the first carrier 102 may be a glass carrier or any suitable carrier for carrying a semiconductor wafer or a reconstituted wafer for the manufacturing method of the semiconductor package. In some embodiments, the first carrier 102 is coated with a debond layer 104. The material of the debond layer 104 may be any material suitable for bonding and de-bonding the first carrier 102 from the above layer(s) or any wafer(s) disposed thereon.

In some embodiments, the debond layer 104 may include a dielectric material layer made of a dielectric material including any suitable polymer-based dielectric material (such as benzocyclobutene (“BCB”), polybenzoxazole (“PBO”)). In an alternative embodiment, the debond layer 104 may include a dielectric material layer made of an epoxy-based thermal-release material, which loses its adhesive property when heated, such as a light-to-heat-conversion (LTHC) release coating film. In a further alternative embodiment, the debond layer 104 may include a dielectric material layer made of an ultra-violet (UV) glue, which loses its adhesive property when exposed to UV lights. In certain embodiments, the debond layer 104 may be dispensed as a liquid and cured, or may be a laminate film laminated onto the first carrier 102, or may be the like. The top surface of the debond layer 104, which is opposite to a bottom surface contacting the first carrier 102, may be levelled and may have a high degree of coplanarity. In certain embodiments, the debond layer 104 is, for example, a LTHC layer with good chemical resistance, and such layer enables room temperature de-bonding from the first carrier 102 by applying laser irradiation, however the disclosure is not limited thereto.

In an alternative embodiment, a buffer layer (not shown) may be coated on the debond layer 104, where the debond layer 104 is sandwiched between the buffer layer and the first carrier 102, and the top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

Referring still to FIG. 1, in a subsequent step, a plurality of first semiconductor dies 106 are placed on the first carrier 102 over the debond layer 104. The first semiconductor dies 106 includes an active surface 106-AS and a backside surface 106-BS, wherein the first semiconductor dies 106 are placed on the first carrier 102 so that the active surface 106-AS is facing the debond layer 104, while the backside surface 106-BS is facing away from the debond layer 104. In the exemplary embodiment, each of the first semiconductor dies 106 includes a semiconductor substrate 106A, a buffer layer 106B disposed on the semiconductor substrate 106A and an interconnection layer 106C (die interconnection layer) disposed on the buffer layer 106B. The semiconductor substrate 106A may be a bulk silicon substrate or a silicon-on-insulator (SOI) substrate, and further includes active components (e.g., transistors or the like) and optionally passive components (e.g., resistors, capacitors, inductors or the like) formed therein. The buffer layer 106B is formed on the semiconductor substrate 106A, and may include polyimide, polybenzoxazole (PBO), benzocyclobutene (BCB), or any other suitable dielectric material.

In some embodiments, the interconnection layer 106C is formed on the buffer layer 106B and includes a plurality of metal lines 106C-1, a plurality of metal vias (not shown), and a plurality of dielectric layers 106C-2 that are alternately stacked. The dielectric layers 106C-2 may be formed, for example, of a low dielectric constant (low-K) dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like. Furthermore, the dielectric layers 106C-2 may be formed by any suitable methods, such as spin coating, chemical vapor deposition (CVD), and/or plasma-enhanced CVD (PECVD), combinations thereof, or the like. In some embodiment, the metal lines 106C-1 and/or vias (not shown) are formed inside the dielectric layers 106C-2 to provide an electrical connection to the electrical circuitry formed in the semiconductor substrate 106A. Although not particularly shown in FIG. 1, in some embodiments, the interconnection layer 106C may further include contact pads formed on the uppermost dielectric layers 106C-2 and a passivation layer partially covering the contact pads.

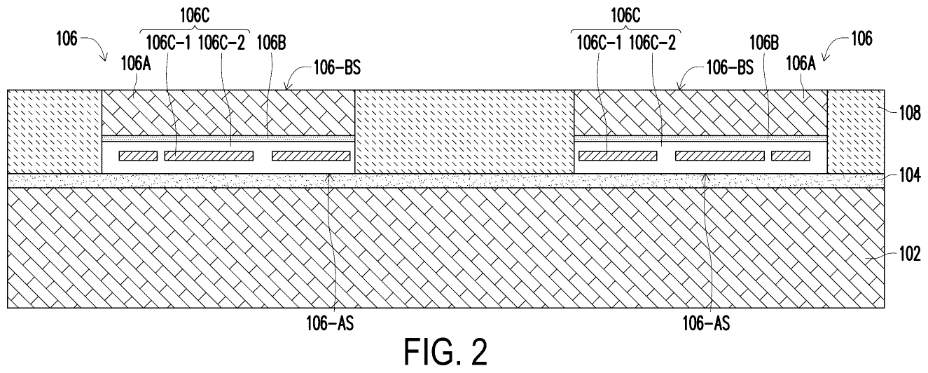

Referring to FIG. 2, after placing the plurality of first semiconductor dies 106 on the first carrier 102, an insulating encapsulant 108 (or molding compound) is formed to encapsulate the first semiconductor dies 106. For example, the insulating encapsulant 108 is formed to laterally surround the first semiconductor dies 106. In some embodiments, the insulating encapsulant 108 is formed through, for example, a compression molding process or transfer molding. In one embodiment, a curing process is performed to cure the insulating encapsulant 108.

In some embodiments, a material of the insulating encapsulant 108 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 108 may include an acceptable insulating encapsulation material. In some embodiments, the insulating encapsulant 108 may further include inorganic filler or inorganic compound (e.g. silica, clay, and so on) which can be added therein to optimize coefficient of thermal expansion (CTE) of the insulating encapsulant 108. The disclosure is not limited thereto.

After forming the insulating encapsulant 108, portions of the insulating encapsulant 108 and portions of the backside surfaces 106-BS of the first semiconductor dies 106 are removed. For example, the insulating encapsulant 108 and the backside surfaces 106-BS of the first semiconductor dies 106 are ground or polished by a planarization step, such as a mechanical grinding process and/or a chemical mechanical polishing (CMP) process. After the planarization step, the backside surfaces 106-BS of the first semiconductor dies 106 and a surface of the insulating encapsulant 108 are coplanar and levelled with one another. In some embodiments, after the mechanical grinding or chemical mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods.

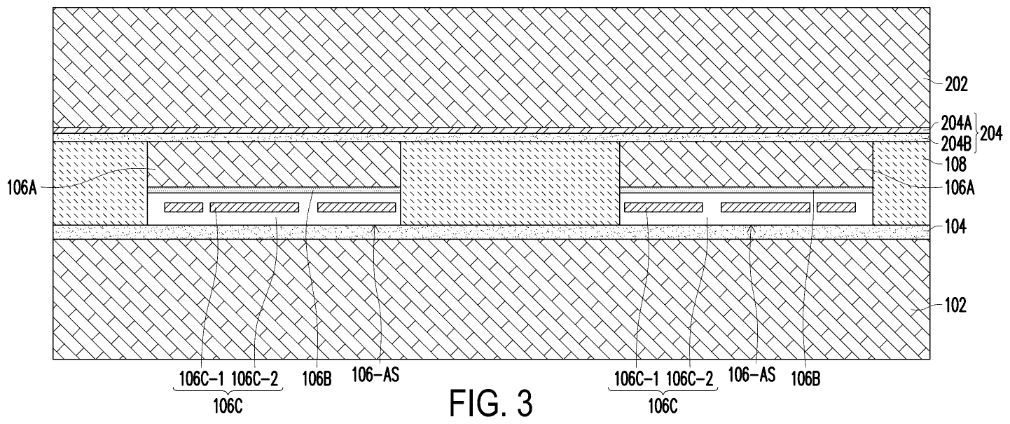

Referring to FIG. 3, in a subsequent step, a second carrier 202 is bonded to the backside surfaces 106-BS of the first semiconductor dies 106 through a buffer layer 204. For example, the buffer layer 204 is located in between the insulating encapsulant 108 and the second carrier 202. The second carrier 202 may be a glass carrier or any suitable carrier for carrying a semiconductor wafer or a reconstituted wafer used for the method of fabricating the semiconductor package. In some embodiments, the buffer layer 204 includes, for example, a debonding layer 204A and a dielectric layer 204B. In certain embodiments, the debonding layer 204A is a light-to-heat conversion (LTHC) release layer. Furthermore, in some embodiments, the dielectric layer 204B may be made of dielectric materials such as benzocyclobutene (“BCB”), polybenzoxazole (“PBO”), or any other suitable polymer-based dielectric material. However, the materials of the carrier 202, the debonding layer 204A and the dielectric layer 204B are not limited to the descriptions of the embodiments. In some alternative embodiments, the dielectric layer 204B may be omitted; in other words, merely the debonding layer 204A is formed over the carrier 202.

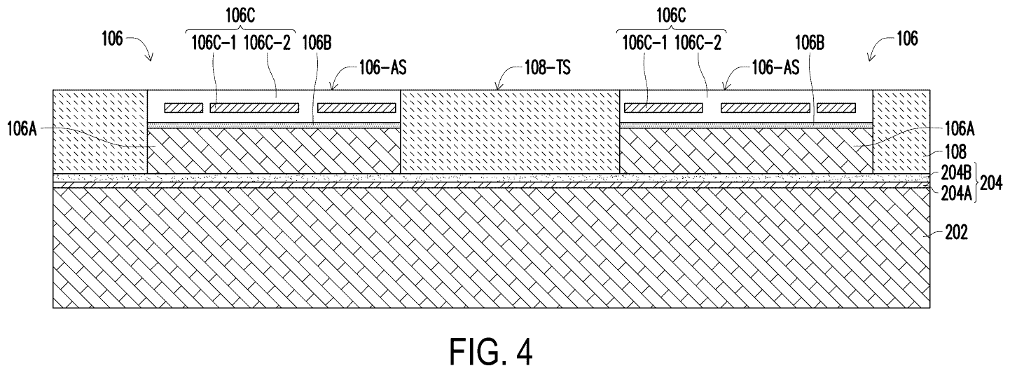

Referring to FIG. 4, the structure shown in FIG. 3 is flipped around, and the first carrier 102 is debonded so as to separate the first semiconductor dies 106 from the first carrier 102. In some embodiments, the debonding process include projecting a light such as a laser light or an UV light on the debond layer 104, so that the first carrier 102 can be easily removed. As illustrated in FIG. 4, upon removing the first carrier 102, the first semiconductor dies 106 are located on the second carrier so that the backside surfaces 106-BS of the first semiconductor dies 106 are contacting the buffer layer 204. Furthermore, active surfaces 106-AS of the first semiconductor dies 106 are coplanar and levelled with a top surface 108-TS of the insulating encapsulant 108.

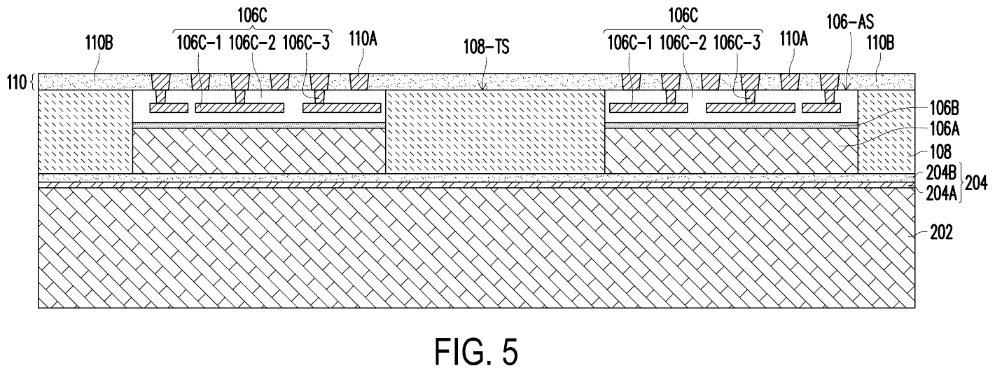

Referring to FIG. 5, after debonding the first carrier 102, a first bonding layer 110 is formed on the first semiconductor dies 106 and the insulating encapsulant 108. In some embodiments, prior to forming the first bonding layer 110, the interconnection layer 106C of the first semiconductor dies 106 are patterned to form openings revealing the topmost metal lines 106C-1 (or contact pads), thereafter, metal vias 106C-3 are formed in the openings and are electrically connected to the topmost metal lines 106C-1 (or contact pads). The metal lines 106C-1, the metal vias 106C-3 and the dielectric layers 106C-2 together constitute the interconnection layer 106C. After forming the metal vias 106C-3, the first bonding layer 110 is formed on the first semiconductor dies 106 and electrically connected to the metal vias 106C-3 of the first semiconductor dies 106. In some embodiments, forming the first bonding layer 110 includes forming a plurality of first bonding pads 110A disposed on and electrically connected to the interconnection layer 106C of the first semiconductor dies 106, and forming a dielectric layer 110B surrounding the first bonding pads 110A.

In some embodiments, the first bonding pads 110A are made of conductive materials formed by electroplating or deposition, and include materials such as copper, copper alloys, or other suitable metallic materials which may be patterned using a photolithography and etching process. Furthermore, the dielectric layer 110B may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 110B is formed by suitable fabrication techniques such as spin-on coating, chemical vapor deposition (CVD), plasma-enhanced chemical vapor deposition (PECVD) or the like. The disclosure is not limited thereto.

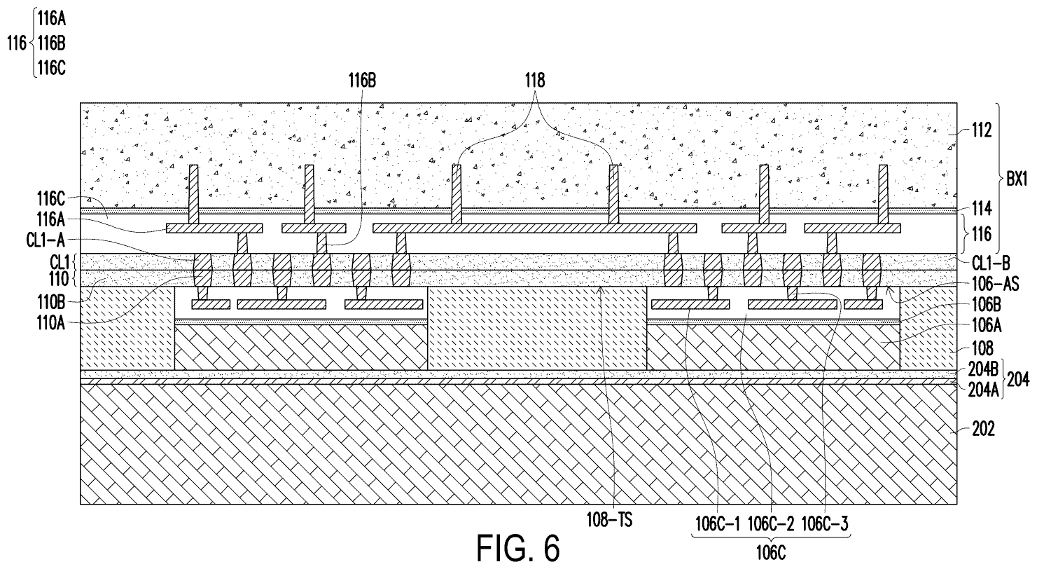

Referring to FIG. 6, in a subsequent step, a bridge layer BX1 (or interposer structure) is bonded to the first bonding layer 110 through a first connection layer CL1. For example, the first connection layer CL1 is first formed on a surface of the bridge layer BX1 so that the first connection layer CL1 can be bonded to the first bonding layer 110 along with the bridge layer BX1. In some embodiments, the first connection layer CL1 includes a plurality of connection pads CL1-A and a dielectric layer CL1-B surrounding the connection pads CL1-A. In some embodiments, the connection pads CL1-A are made of conductive materials formed by electroplating or deposition, and include materials such as copper, copper alloys, or other suitable metallic materials which may be patterned using a photolithography and etching process. Furthermore, the dielectric layer CL1-B may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer CL1-B is formed by suitable fabrication techniques such as spin-on coating, chemical vapor deposition (CVD), plasma-enhanced chemical vapor deposition (PECVD) or the like. The disclosure is not limited thereto.

In some embodiments, the first connection layer CL1 is bonded to the first bonding layer 110 using dielectric-to-dielectric bonding and metal-to-metal bonding. For example, the dielectric layer CL1-B of the first connection layer CL1 is directly joined with the dielectric layer 110B of the first bonding layer 110 using dielectric-to-dielectric bonding, while the connection pads CL1-A are directly joined with the first bonding pads 110A using metal-to-metal bonding. After bonding the first connection layer CL1 to the first bonding layer 110, the first connection layer CL1 is sandwiched in between the bridge layer BX1 and the first bonding layer 110. In some embodiments, a width of the first bonding pads 110A increases along a build-up direction (stacking direction), while a width of the connection pads CL1-A decreases along the build-up direction (stacking direction). In other words, a surface of the first bonding pads 110A joined with the connection pads CL1-A is greater than a surface of the first bonding pads 110A joined with the interconnection layer 106C. Similarly, a surface of the connection pads CL1-A joined with the first bonding pads 110A is greater than a surface of the connection pads CL1-A joined with the interconnection layer 116.

In the exemplary embodiment, the bridge layer BX1 includes a substrate structure 112, a buffer layer 114 disposed on the substrate structure 112, an interconnection layer disposed on the substrate structure 112 over the buffer layer 114, and through vias 118 extending from the interconnection layer 116 into the substrate structure 112. In some embodiments, the substrate structure 112 is for example, a silicon wafer. In some alternative embodiments, the substrate structure 112 may be silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, or combinations thereof, and may be doped or undoped. The buffer layer 114 may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like.

The interconnection layer 116 is formed on the buffer layer 114 and includes a plurality of conductive lines 116A, a plurality of conductive vias 116B, and one or more dielectric layers 116C that are alternately stacked. In some embodiments, the interconnection layer 116 is electrically connected to the first connection layer CL1 by electrically joining the conductive vias 116B to the connection pads CL1-A. In some embodiments, the conductive lines 116A and the conductive vias 116B are formed by an electro-chemical plating process, chemical vapor deposition (CVD), atomic layer deposition (ALD) or physical vapor deposition (PVD) of a conductive material such as copper, tungsten, aluminum, silver, gold or a combination thereof.

The dielectric layers 116C may be formed of silicon oxide, silicon nitride, silicon carbide, silicon oxynitride, or low-K dielectric materials (such as phosphosilicate glass materials, fluorosilicate glass materials, boro-phosphosilicate glass materials, SiOC, spin-on-glass materials, spin-on-polymers or silicon carbon materials). In some embodiments, the dielectric layers 116C may be formed by spin-coating or deposition, including chemical vapor deposition (CVD), PECVD, high density plasma CVD (HDP-CVD), or the like. In certain embodiments, the through vias 118 are formed of a material similar to a material of the conductive lines 116A and the conductive vias 116B, and the through vias 118 are physically and electrically connected to the conductive lines 116A of the interconnection layer 116.

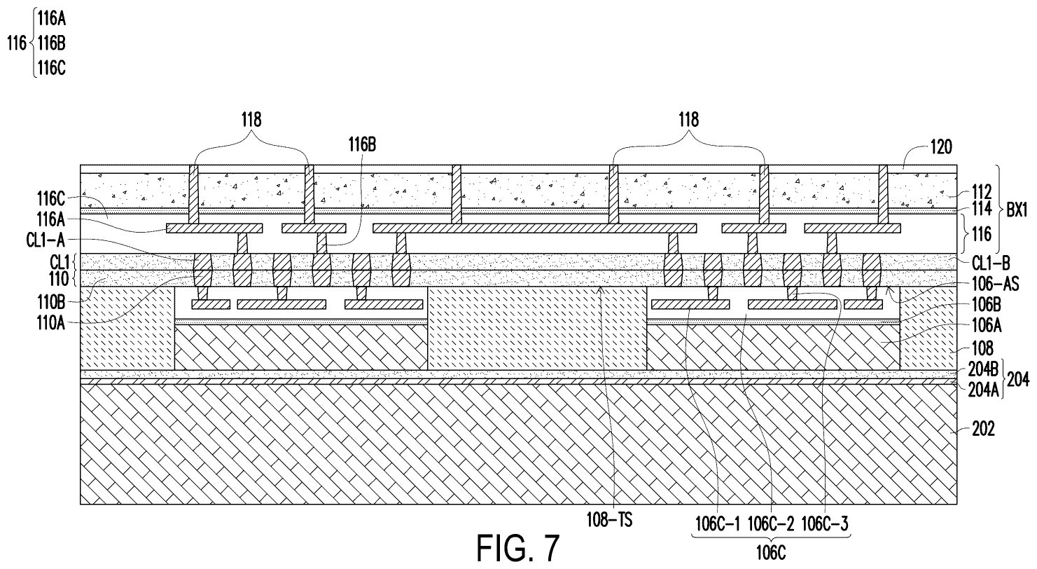

Referring to FIG. 7, after bonding the bridge layer BX1 onto the first bonding layer 110, the substrate structure 112 is thinned down to reveal the through vias 118. In some embodiments, the substrate structure 112 is further recessed, for example through an etching process, so that the through vias 118 are protruding out from the substrate structure 112. In certain embodiments, a passivation layer 120 is formed on the substrate structure 112 to laterally surround the through vias 118. For example, the passivation layer 120 is formed by depositing a dielectric layer, which may be formed of silicon oxide, silicon nitride, or the like, and performing a planarization process to remove the excess portions of the dielectric material over the through vias 118, so that the through vias 118 are revealed.

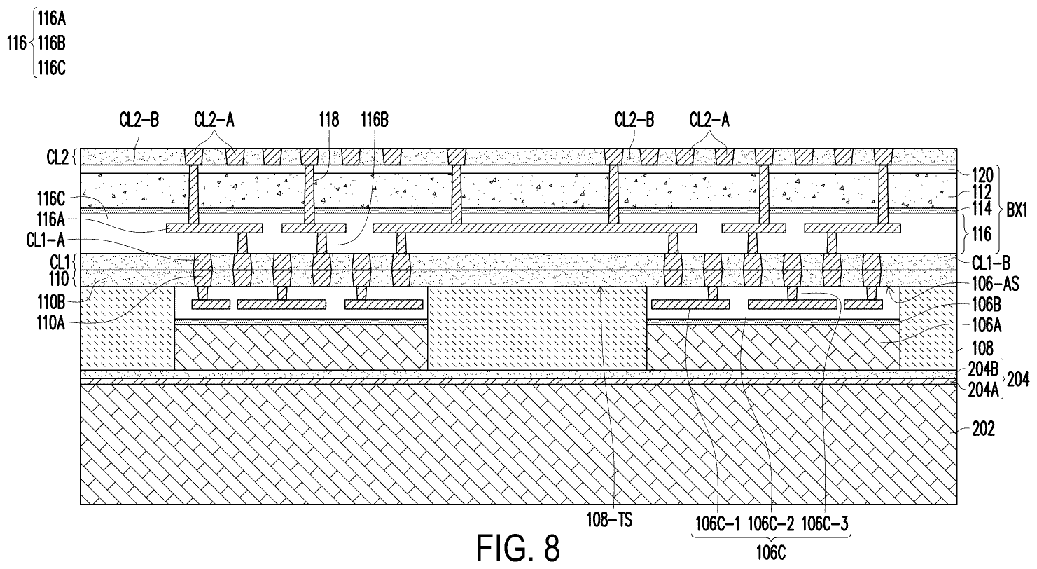

Referring to FIG. 8, in a subsequent step, a second connection layer CL2 is formed on the bridge layer BX1 and electrically connected to the bridge layer BX1. In some embodiments, the second connection layer CL2 includes a plurality of connection pads CL2-A and a dielectric layer CL2-B surrounding the connection pads CL2-A. In some embodiments, the connection pads CL2-A are made of conductive materials formed by electroplating or deposition, and include materials such as copper, copper alloys, or other suitable metallic materials which may be patterned using a photolithography and etching process. Furthermore, the dielectric layer CL2-B may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer CL2-B is formed by suitable fabrication techniques such as spin-on coating, chemical vapor deposition (CVD), plasma-enhanced chemical vapor deposition (PECVD) or the like. The disclosure is not limited thereto. In certain embodiments, the second connection layer CL2 is electrically connected to the bridge layer BX1 by joining the connection pads CL2-A to the through vias 118.

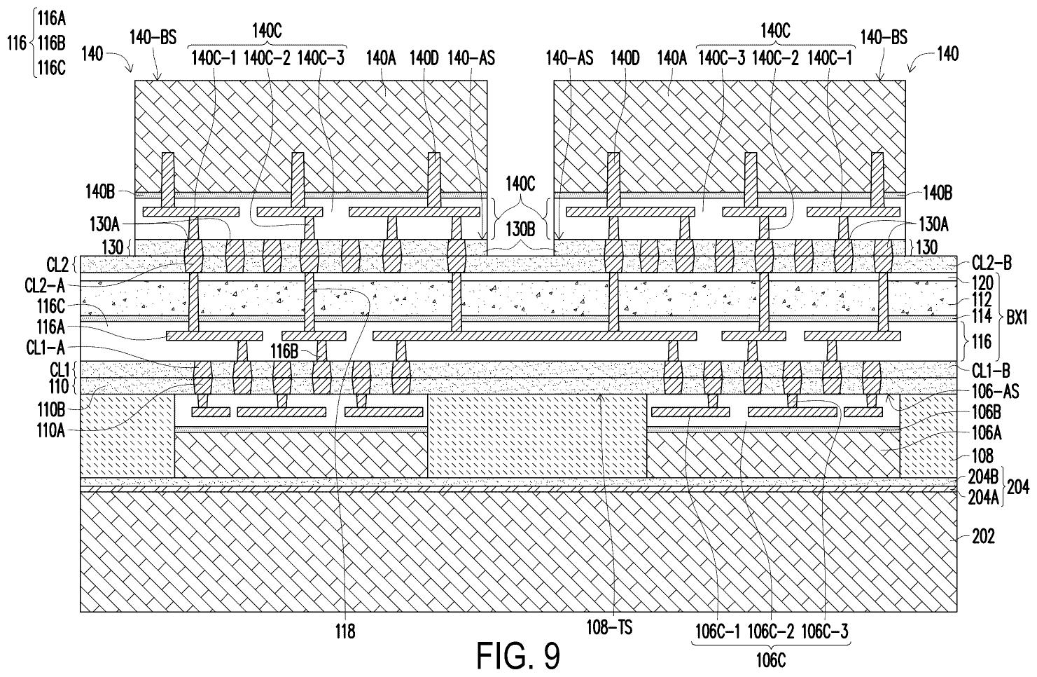

Referring to FIG. 9, after forming the second connection layer CL2, a plurality of second semiconductor dies 140 is bonded to the second connection layer CL2 through a second bonding layer 130. For example, the second bonding layer 130 is first formed on an active surface 140-AS of the second semiconductor dies 140 so that the second bonding layer 130 can be bonded to the second connection layer CL2 along with the second semiconductor dies 140. In some embodiments, the second semiconductor dies 140 and the second bonding layer 130 are placed over the second connection layer CL2 by, e.g., a pick-and-place process. In some embodiments, forming the second bonding layer 130 includes forming a plurality of second bonding pads 130A disposed on and electrically connected to the second semiconductor dies 140, and forming a dielectric layer 130B surrounding the second bonding pads 130A.

In some embodiments, the second bonding pads 130A are made of conductive materials formed by electroplating or deposition, and include materials such as copper, copper alloys, or other suitable metallic materials which may be patterned using a photolithography and etching process. Furthermore, the dielectric layer 130B may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 130B is formed by suitable fabrication techniques such as spin-on coating, chemical vapor deposition (CVD), plasma-enhanced chemical vapor deposition (PECVD) or the like. The disclosure is not limited thereto.

As illustrated in FIG. 9, the second bonding layer 130 is bonded to the second connection layer CL2 using dielectric-to-dielectric bonding and metal-to-metal bonding. For example, the dielectric layer CL2-B of the second connection layer CL2 is directly joined with the dielectric layer 130B of the second bonding layer 130 using dielectric-to-dielectric bonding, while the connection pads CL2-A are directly joined with the second bonding pads 130A using metal-to-metal bonding. After bonding the second bonding layer 130 to the second connection layer CL2, the second connection layer CL2 is sandwiched in between the bridge layer BX1 and the second bonding layer 130. In some embodiments, a width of the connection pads CL2-A increases along a build-up direction (stacking direction), while a width of the second bonding pads 130A decreases along the build-up direction (stacking direction). In other words, a surface of the connection pads CL2-A joined with the second bonding pads 130A is greater than a surface of the connection pads CL2-A joined with the bridge layer BX1. Similarly, a surface of the second bonding pads 130A joined with the connection pads CL2-A is greater than a surface of the second bonding pads 130A joined with the second semiconductor dies 140.

As further illustrated in FIG. 9, the second semiconductor dies 140 are bonded onto the second connection layer CL2 so that the active surface 140-AS is facing the active surface 106-AS of the first semiconductor dies 106. In other words, the first semiconductor dies 106 and the second semiconductor dies 140 are arranged in a face-to-face manner. In the exemplary embodiment, each of the second semiconductor dies 140 includes a semiconductor substrate 140A, a buffer layer 140B disposed on the semiconductor substrate 140A, an interconnection layer 140C (die interconnection layer) disposed on the buffer layer 1140B, and backside vias 140D extending from the interconnection layer 140C to the semiconductor substrate 140A. The semiconductor substrate 140A may be a bulk silicon substrate or a silicon-on-insulator (SOI) substrate, and further includes active components (e.g., transistors or the like) and optionally passive components (e.g., resistors, capacitors, inductors or the like) formed therein. The buffer layer 140B is formed on the semiconductor substrate 140A, and may include polyimide, polybenzoxazole (PBO), benzocyclobutene (BCB), or any other suitable dielectric material.

In some embodiments, the interconnection layer 140C is formed on the buffer layer 140B and includes a plurality of conductive lines 140C-1, a plurality of conductive vias 140C-2, and a plurality of dielectric layers 140C-3 that are alternately stacked. The dielectric layers 140C-3 may be formed, for example, of a low dielectric constant (low-K) dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like. Furthermore, the dielectric layers 140C-3 may be formed by any suitable methods, such as spin coating, chemical vapor deposition (CVD), and/or plasma-enhanced CVD (PECVD), combinations thereof, or the like. In some embodiment, the conductive lines 140C-1 and/or conductive vias 140C-2 are formed inside the dielectric layers 140C-3 to provide an electrical connection to the electrical circuitry formed in the semiconductor substrate 140A. Although not particularly shown in FIG. 9, in some embodiments, the interconnection layer 140C may further include contact pads formed on the uppermost dielectric layers 140C-3 and a passivation layer partially covering the contact pads. In some embodiments, the interconnection layer 140C is electrically connected to the second bonding layer 130 by electrically joining the conductive vias 140C-2 to the second bonding pads 130A. In certain embodiments, the backside vias 140D are electrically connected to the conductive lines 140C-1 of the interconnection layer 140C, wherein the backside vias 140D are formed by electroplating or deposition of a metal material such as copper or copper alloys, or the like.

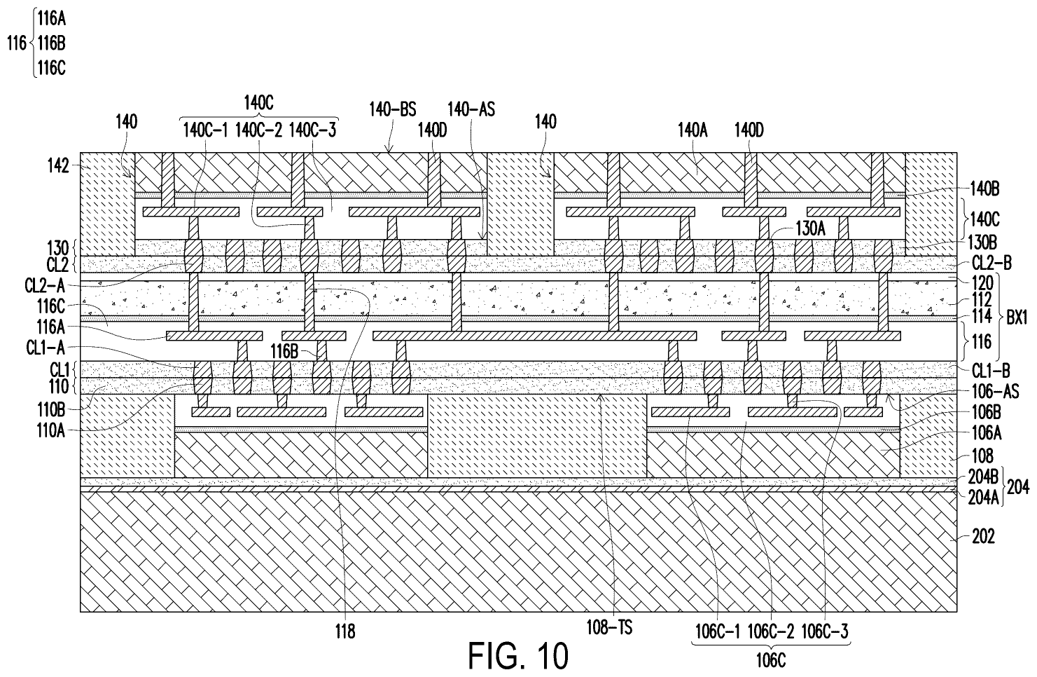

Referring to FIG. 10, in a subsequent step, an insulating encapsulant 142 (or molding compound) is formed to encapsulate the second semiconductor dies 140. For example, the insulating encapsulant 142 is formed to laterally surround the second semiconductor dies 140. In some embodiments, the insulating encapsulant 142 is formed through, for example, a compression molding process or transfer molding. In one embodiment, a curing process is performed to cure the insulating encapsulant 142.

In some embodiments, a material of the insulating encapsulant 142 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 142 may include an acceptable insulating encapsulation material. In some embodiments, the insulating encapsulant 142 may further include inorganic filler or inorganic compound (e.g. silica, clay, and so on) which can be added therein to optimize coefficient of thermal expansion (CTE) of the insulating encapsulant 142. The disclosure is not limited thereto.

After forming the insulating encapsulant 142, portions of the insulating encapsulant 142 and portions of the backside surfaces 140-BS of the second semiconductor dies 140 are removed. For example, the insulating encapsulant 142 and the backside surfaces 140-BS of the second semiconductor dies 140 are ground or polished by a planarization step, such as a mechanical grinding process and/or a chemical mechanical polishing (CMP) process. After the planarization step, the backside vias 140D are revealed, and the backside surfaces 140-BS of the second semiconductor dies 140 and a surface of the insulating encapsulant 142 are coplanar and levelled with one another. In some embodiments, after the mechanical grinding or chemical mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods.

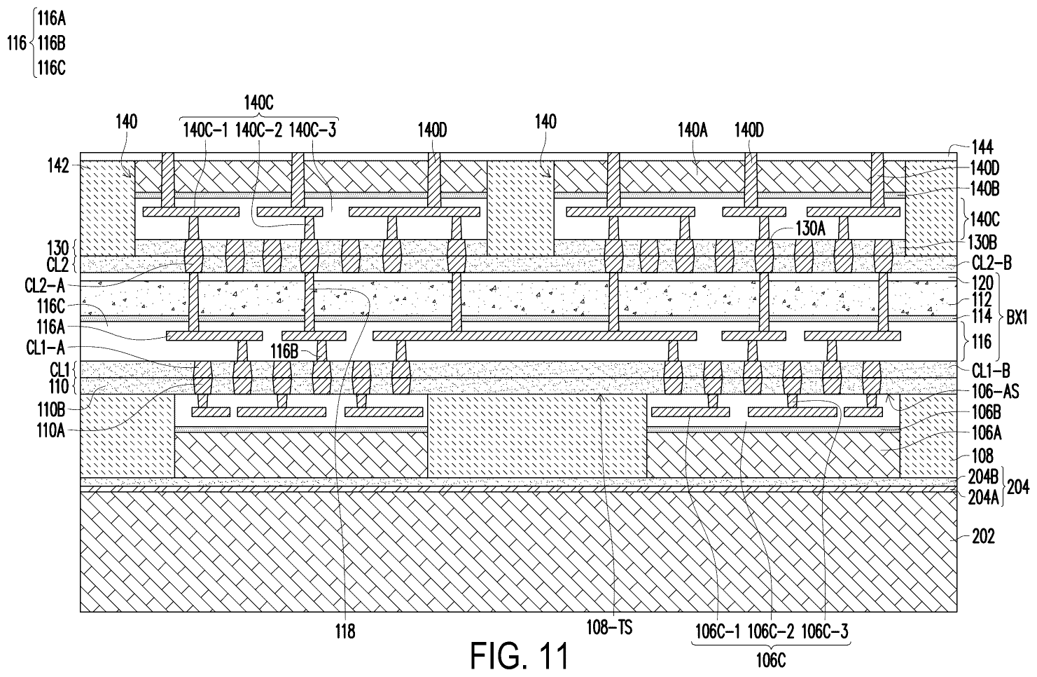

Referring to FIG. 11, in a subsequent step, the insulating encapsulant 142 and the semiconductor substrate 140A may be further recessed, for example through an etching process, so that the backside vias 140D are protruding out from the semiconductor substrate 140A. In some embodiments, a passivation layer 144 is formed on the semiconductor substrate 140A and the insulating encapsulant 142. For example, the passivation layer 144 is formed by depositing a dielectric layer, which may be formed of silicon oxide, silicon nitride, or the like, and performing a planarization process to remove the excess portions of the dielectric material over the backside vias 140D, so that the backside vias 140D are revealed.

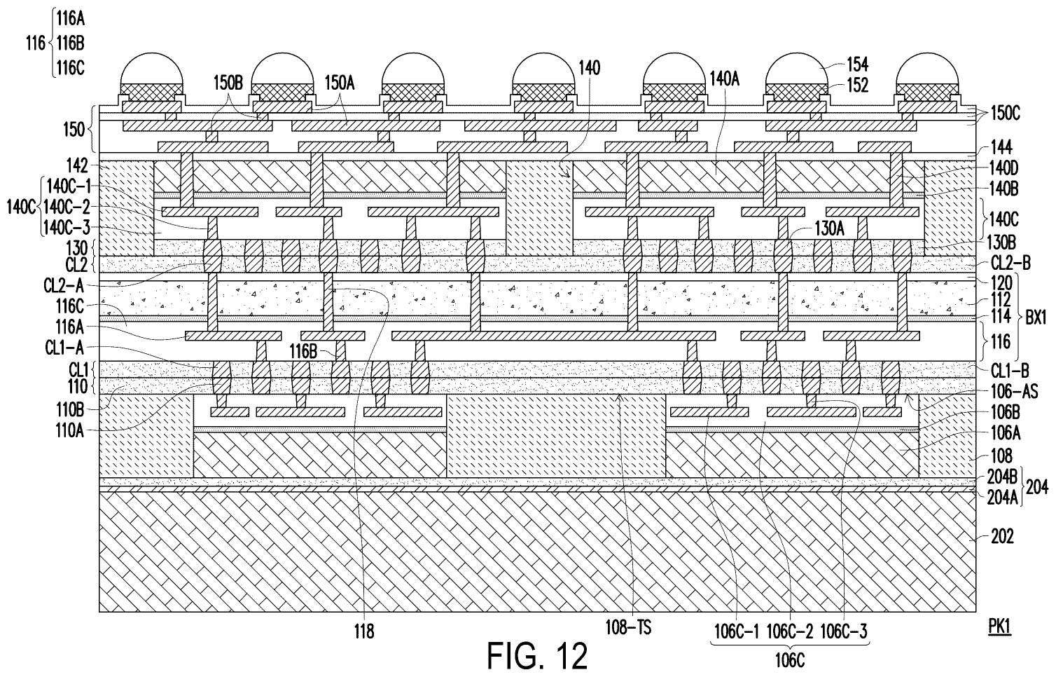

Referring to FIG. 12, after forming the passivation layer 144, a redistribution layer 150 is formed on the backside surfaces 140-BS of the second semiconductor dies 140. For example, the redistribution layer 150 is physically and electrically connected to the backside vias 140D of the second semiconductor dies 140. In some embodiments, the formation of the redistribution layer 150 includes sequentially forming one or more dielectric layers 150C, one or more metal lines 150A, and one or more metal vias 150B in alternation. In certain embodiments, the metal lines 150A and metal vias 150B are sandwiched between the dielectric layers 150C. Furthermore, the number of layers of dielectric layers 150C, and the number of metal lines 150A and metal vias 150B shown in FIG. 12 are for illustrative purposes, and the scope of the disclosure is not limited by the embodiments herein. In other embodiments, the number of dielectric layers 150C, and the number of metal lines 150A and metal vias 150B may be adjusted based on product requirement. In some embodiments, the redistribution layer 150 is electrically connected to the backside vias 140D of the second semiconductor dies 140 through the metal lines 150A or the metal vias 150B.

In some embodiments, a material of the dielectric layers 150C may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers DI1 may be formed by suitable fabrication techniques such as spin-on coating, chemical vapor deposition (CVD), plasma-enhanced chemical vapor deposition (PECVD) or the like. The disclosure is not limited thereto.

In some embodiments, the material of the metal lines 150A and metal vias 150B may be made of conductive materials formed by electroplating or deposition, such as aluminum, titanium, copper, nickel, tungsten, and/or alloys thereof, which may be patterned using a photolithography and etching process. In some embodiments, the metal lines 150A and metal vias 150B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

After forming the redistribution layer 150, a plurality of conductive pads 152 are disposed on an exposed top surface of the topmost layer of the metal lines 150A for electrically connecting with conductive terminals. In certain embodiments, the conductive pads 152 are for example, under-ball metallurgy (UBM) patterns used for ball mount. As shown in FIG. 12, the conductive pads 152 are formed on and electrically connected to the redistribution layer 150. In some embodiments, the materials of the conductive pads 152 may include copper, nickel, titanium, tungsten, or alloys thereof or the like, and may be formed by an electroplating process, for example. The number of conductive pads 152 are not limited in this disclosure, and may be selected based on the design layout. In some alternative embodiments, the conductive pads 152 may be omitted. In other words, conductive terminals 154 formed in subsequent steps may be directly disposed on the redistribution layer 150.

After forming the conductive pads 152, a plurality of conductive terminals 154 is disposed on the conductive pads 152 and over the redistribution layer 150. In some embodiments, the conductive terminals 154 may be disposed on the conductive pads 152 by a ball placement process or reflow process. In some embodiments, the conductive terminals 154 are, for example, solder balls or ball grid array (BGA) balls. In some embodiments, the conductive terminals 154 are connected to the redistribution layer 150 through the conductive pads 152. In certain embodiments, the conductive terminals 154 may be electrically connected to the second semiconductor dies 140 through the redistribution layer 150. The number of the conductive terminals 154 is not limited to the disclosure, and may be designated and selected based on the number of the conductive pads 152. After forming the conductive pads 152 and conductive terminals 154, multiple semiconductor packages PK1 including the above package components are formed on the same carrier substrate(s) and then singulated to form individual semiconductor package PK1. In the semiconductor package PK1, since a bridge layer BX1 is provided between the first semiconductor dies 106 and the second semiconductor dies 140, die to die signals can be transferred both horizontally and vertically, allowing multiple data transferring path between die-to-die areas for signal communication. As such, with the additional signal transferring paths, the semiconductor package PK1 can be used for super powerful data processing.

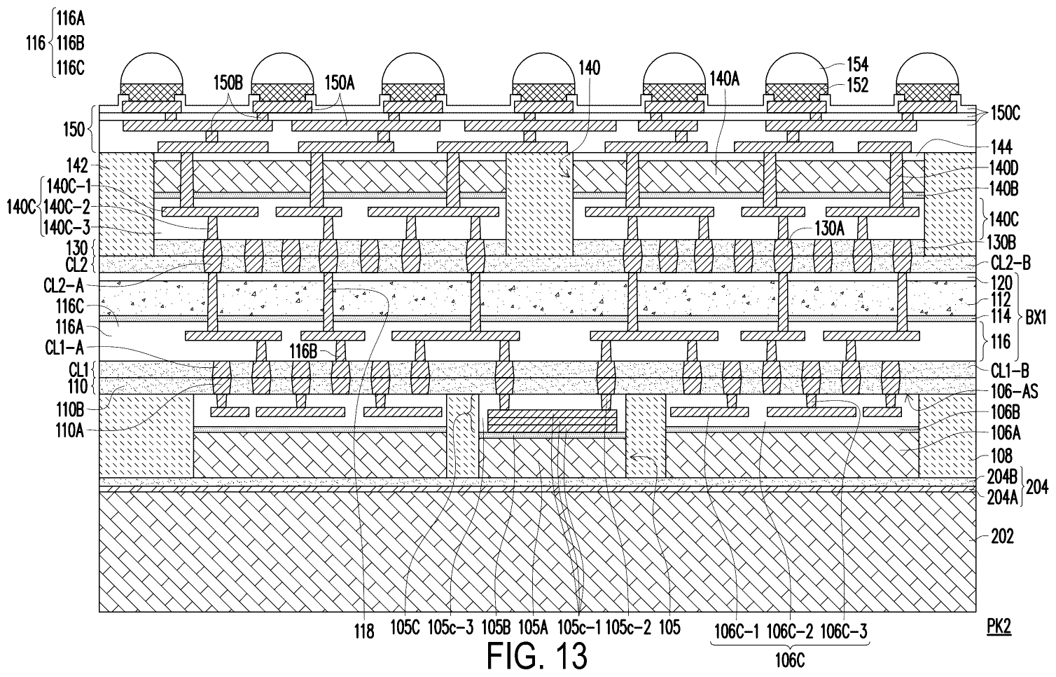

FIG. 13 is a schematic sectional view of a semiconductor package according to some exemplary embodiments of the present disclosure. The semiconductor package PK2 illustrated in FIG. 13 is similar to the semiconductor package PK1 illustrated in FIG. 12. Therefore, the same reference numerals are used to refer to the same or like parts, and its detailed description are omitted herein. The difference between the semiconductor package PK1 of FIG. 12 and the semiconductor package PK2 of FIG. 13 is that a bridge die 105 is further provided in the semiconductor package PK2.

As illustrated in FIG. 13, the bridge die 105 includes a semiconductor substrate 105A, a buffer layer 105B disposed on the semiconductor substrate 105A, and an interconnection layer 105C (die interconnection layer) disposed on the buffer layer 105B. The semiconductor substrate 105A may be a bulk silicon substrate or a silicon-on-insulator (SOI) substrate, and further includes active components (e.g., transistors or the like) and optionally passive components (e.g., resistors, capacitors, inductors or the like) formed therein. The buffer layer 105B is formed on the semiconductor substrate 105A, and may include polyimide, polybenzoxazole (PBO), benzocyclobutene (BCB), or any other suitable dielectric material.

In some embodiments, the interconnection layer 105C is formed on the buffer layer 105B and includes a plurality of conductive lines 105c-1, a plurality of conductive vias 105c-2, and a plurality of dielectric layers 105c-3 that are alternately stacked. The dielectric layers 105c-3 may be formed, for example, of a low dielectric constant (low-K) dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like. Furthermore, the dielectric layers 105c-3 may be formed by any suitable methods, such as spin coating, chemical vapor deposition (CVD), and/or plasma-enhanced CVD (PECVD), combinations thereof, or the like. In some embodiment, the conductive lines 105c-1 and/or conductive vias 105c-2 are formed inside the dielectric layers 105c-3 to provide an electrical connection to the electrical circuitry formed in the semiconductor substrate 105A. Although not particularly shown in FIG. 13, in some embodiments, the interconnection layer 105C may further include contact pads formed on the uppermost dielectric layers 105c-3 and a passivation layer partially covering the contact pads.

In the exemplary embodiment, the interconnection layer 105C of the bridge die 105 is electrically connected to the first bonding layer 110 by joining the conductive vias 105c-2 to the first bonding pads 110A. In some embodiments, the bridge die 105 is electrically connecting the plurality of second semiconductor dies 140 to one another through the bridge layer BX1. In certain embodiments, the bridge die 105 is electrically connected to the plurality of first semiconductor dies 106. In some embodiments, the bridge die 105 may be local silicon interconnects (LSIs), large scale integration packages, interposer dies, or the like. In the semiconductor package PK2, since a bridge layer BX1 is provided between the first semiconductor dies 106 and the second semiconductor dies 140, and a bridge die 105 is further provided for interconnection, die to die signals can be transferred both horizontally and vertically, allowing multiple data transferring path between die-to-die areas for signal communication. As such, with the additional signal transferring paths, the semiconductor package PK2 can be used for super powerful data processing.

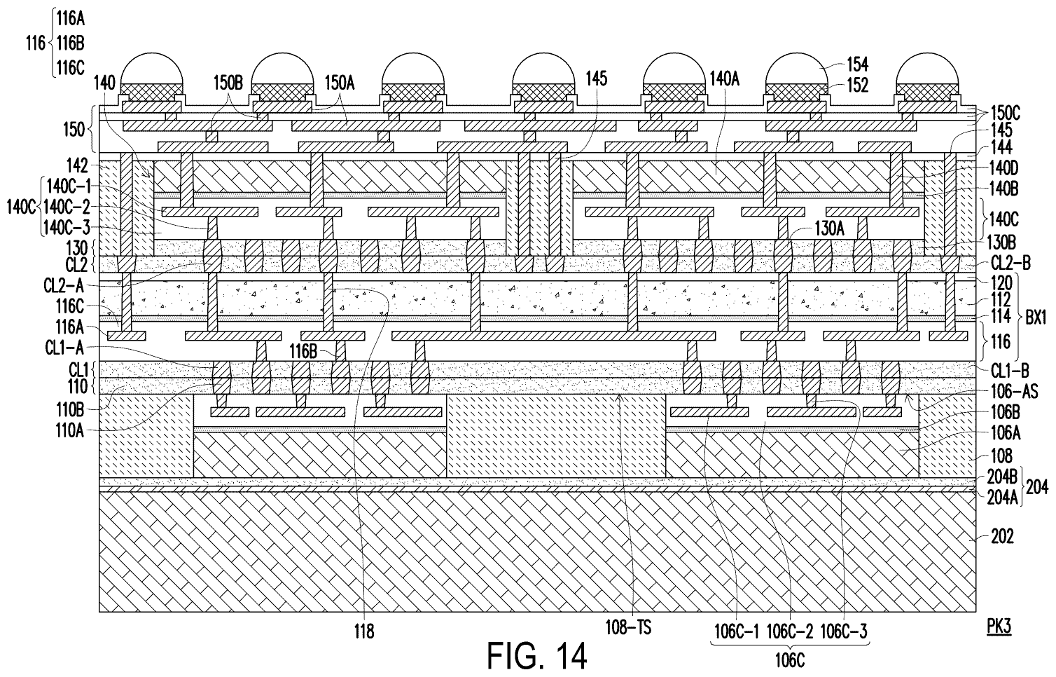

FIG. 14 is a schematic sectional view of a semiconductor package according to some other exemplary embodiments of the present disclosure. The semiconductor package PK3 illustrated in FIG. 14 is similar to the semiconductor package PK1 illustrated in FIG. 12. Therefore, the same reference numerals are used to refer to the same or like parts, and its detailed description are omitted herein. The difference between the semiconductor package PK1 of FIG. 12 and the semiconductor package PK3 of FIG. 14 is that through dielectric vias 145 are further formed in the semiconductor package PK3.

As illustrated in FIG. 14, in some embodiments, through dielectric vias 145 are formed to be embedded in the insulating encapsulant 142 and further surrounded by the passivation layer 144. In some embodiments, the through dielectric vias 145 are surrounding the second semiconductor dies 140 and separating the plurality of second semiconductor dies 140 from one another. Furthermore, the through dielectric vias 145 may be electrically connecting the bridge layer BX1 (or interposer structure) to the redistribution layer 150. For example, the through dielectric vias 145 are electrically connected to the bridge layer BX1 through the second connection layer CL2.

In the illustrated embodiment, the through dielectric vias 145 is physically joined with the connection pads CL2-A of the second connection layer CL2, and physically joined with the metal lines 150A of the redistribution layer 150. However, the disclosure is not limited thereto. In an alternative embodiment where the second bonding layer 130 extends beyond sidewalls of the second semiconductor dies 140, and where sidewalls of the second bonding layer 130 are aligned with sidewalls of the second connection layer CL2, the through dielectric vias 145 may be electrically connected to the bridge layer BX1 through an electrical conduction path that passes through the second bonding pads 130A and the connection pads CL2-A to reach the through vias 118 of the bridge layer BX1. In other words, in such an embodiment, the through dielectric vias 145 may be physically attached to the second bonding pads 130A. In the semiconductor package PK3, since a bridge layer BX1 is provided between the first semiconductor dies 106 and the second semiconductor dies 140, and the through dielectric vias 145 are further provided for vertical interconnection, die to die signals can be transferred both horizontally and vertically, allowing multiple data transferring path between die-to-die areas for signal communication. As such, with the additional signal transferring paths, the semiconductor package PK3 can be used for super powerful data processing.

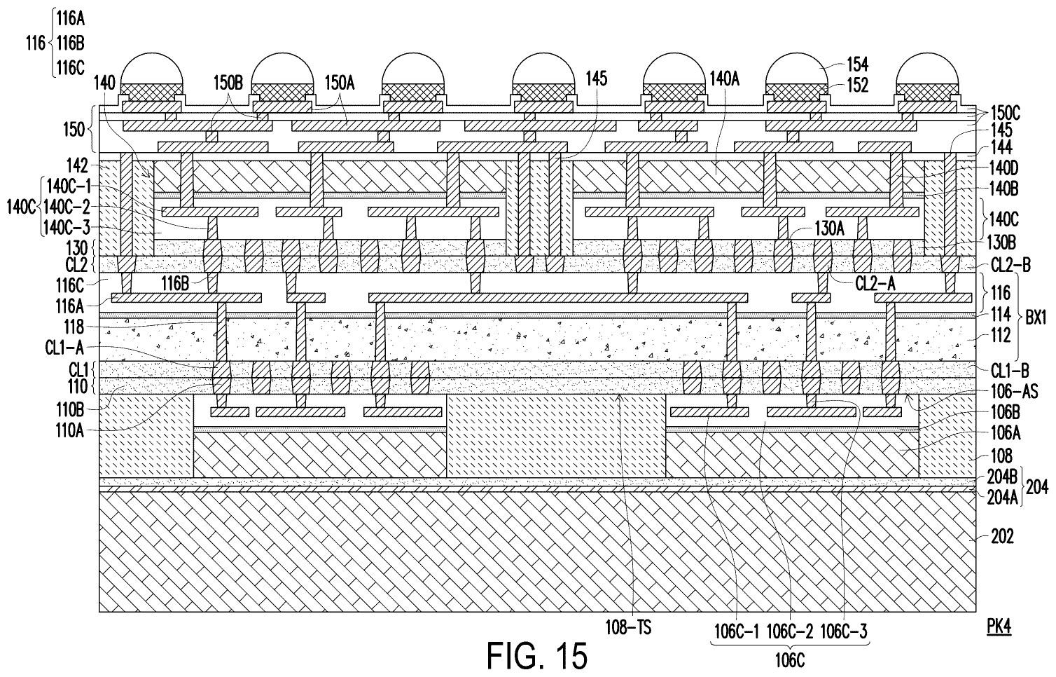

FIG. 15 is a schematic sectional view of a semiconductor package according to some other exemplary embodiments of the present disclosure. The semiconductor package PK4 illustrated in FIG. 15 is similar to the semiconductor package PK3 illustrated in FIG. 14. Therefore, the same reference numerals are used to refer to the same or like parts, and its detailed description are omitted herein. In the previous embodiment, the bridge layer BX1 is sandwiched between the first connection layer CL1 and the second connection layer CL2 so that the substrate structure 112 is provided near the second connection layer CL2, and the interconnection layer 116 is provided near the first connection layer CL1. However, the disclosure is not limited thereto.

As illustrated in FIG. 15, in some embodiments, the bridge layer BX1 is sandwiched between the first connection layer CL1 and the second connection layer CL2 so that the substrate structure 112 is provided near the first connection layer CL1 and the interconnection layer 116 is provided near the second connection layer CL2. For example, the through vias 118 is physically and electrically connecting the interconnection layer 116 to the connection pads CL1-A of the first connection layer CL1, while the conductive vias 116B of the interconnection layer 116 are physically and electrically connected to the connection pads CL2-A of the second connection layer CL2.

In the semiconductor package PK4, since a bridge layer BX1 is provided between the first semiconductor dies 106 and the second semiconductor dies 140, and the through dielectric vias 145 are further provided for vertical interconnection, die to die signals can be transferred both horizontally and vertically, allowing multiple data transferring path between die-to-die areas for signal communication. As such, with the additional signal transferring paths, the semiconductor package PK4 can be used for super powerful data processing.

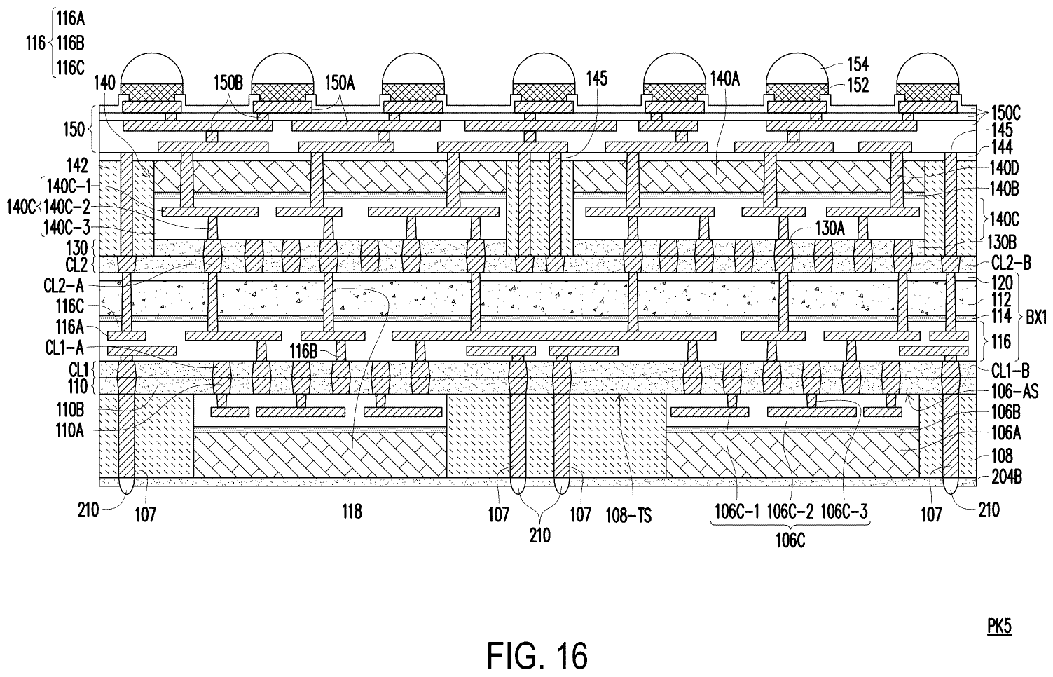

FIG. 16 is a schematic sectional view of a semiconductor package according to some other exemplary embodiments of the present disclosure. The semiconductor package PK5 illustrated in FIG. 16 is similar to the semiconductor package PK3 illustrated in FIG. 14. Therefore, the same reference numerals are used to refer to the same or like parts, and its detailed description are omitted herein.

As illustrated in FIG. 16, in some embodiments, a plurality of through dielectric vias 107 are further formed in the insulating encapsulant 108 to surround the first semiconductor dies 106. In some embodiments, the second carrier 202 shown in the semiconductor package PK3 of FIG. 14 is debonded from the package structure PK5 of FIG. 16. For example, the dielectric layer 204B is separated from the debonding layer 204A and the carrier 202. In some embodiments, the debonding layer 204A (e.g., the LTHC release layer) may be irradiated by an UV laser such that the dielectric layer 204B is peeled from the carrier 202. In certain embodiments, the debonding layer 204A may be further removed or peeled off so that debonding layer 204A is separated from the dielectric layer 204B. As shown in FIG. 16, the remaining dielectric layer 204B may then be patterned to form a plurality of openings revealing the through dielectric vias 107. Thereafter, a plurality of conductive terminals 210 are, for example, reflowed to bond with the bottom surfaces of the through dielectric vias 107. After the conductive terminals 210 are formed, a semiconductor package PK5 having dual-side terminals is accomplished. The conductive terminals 210 allows for providing electrical connection of the semiconductor package PK5 to external components.

In the semiconductor package PK5, since a bridge layer BX1 is provided between the first semiconductor dies 106 and the second semiconductor dies 140, and the through dielectric vias 145, 107 are further provided for vertical interconnection, die to die signals can be transferred both horizontally and vertically, allowing multiple data transferring path between die-to-die areas for signal communication. As such, with the additional signal transferring paths, the semiconductor package PK5 can be used for super powerful data processing.

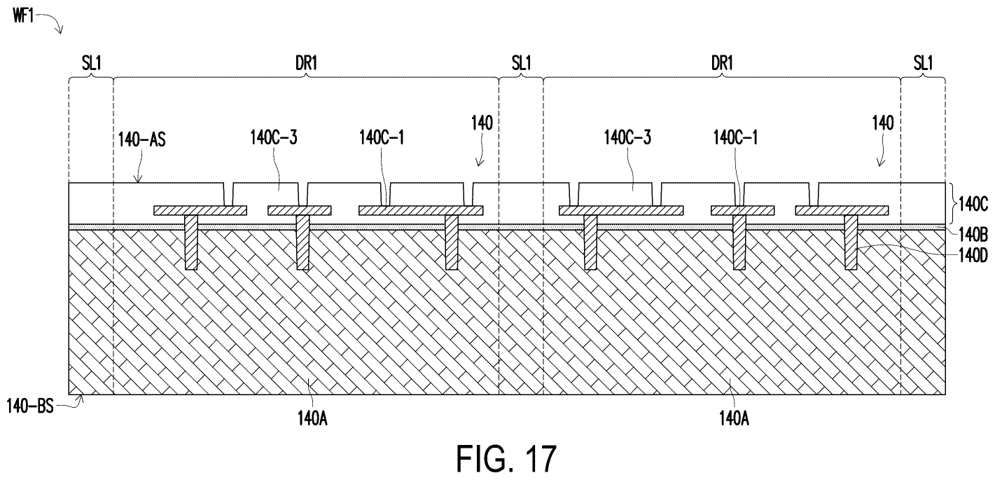

FIG. 17 to FIG. 25 are schematic sectional views of various stages in a method of fabricating a semiconductor package according to some other exemplary embodiments of the present disclosure. The method illustrated in FIG. 17 to FIG. 25 is similar to the method illustrated in FIG. 1 to FIG. 12. Therefore, the same reference numerals are used to refer to the same or like parts, and its detailed description are omitted herein.

As illustrated in FIG. 17, a semiconductor wafer WF1 is provided. The semiconductor wafer WF1 comprises die regions DR1 and scribe line regions SL1. In the exemplary embodiment, the die regions DR1 includes the plurality of second semiconductor dies 140 as described in FIG. 9 to FIG. 12 of the semiconductor package PK1. In other words, the second semiconductor dies 140 are parts of the semiconductor wafer WF1. In certain embodiments, the scribe line regions SL1 are joining the plurality of second semiconductor dies 140 in the die regions DR1 together. For example, in the illustrated embodiment, the semiconductor substrate 140A, the buffer layer 140B, and the interconnection layer 140C may extend from the die regions DR1 to the scribe line regions SL1. Referring to FIG. 17, in some embodiments, the dielectric layers 140C-3 of the interconnection layer 140C is patterned to form openings revealing the conductive lines 140C-1.

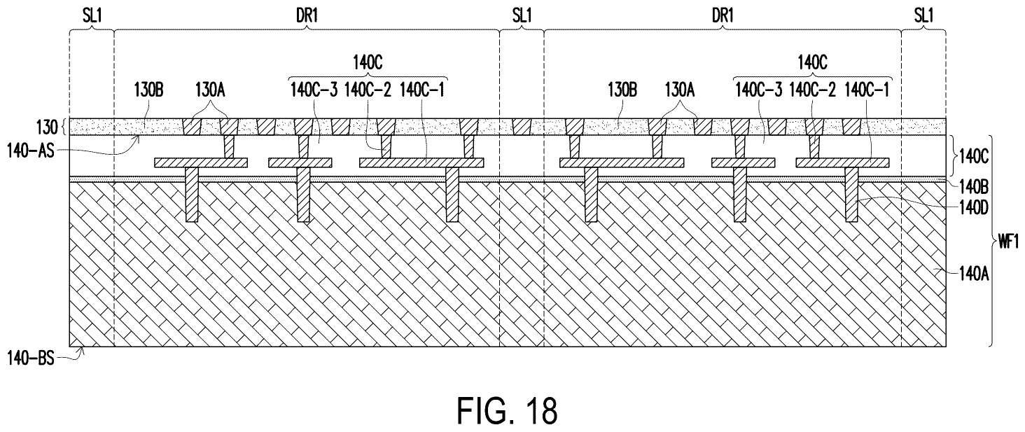

Referring to FIG. 18, the openings are filled with conductive vias 140C-2, wherein the conductive vias 140C-2 are electrically connected to the conductive lines 140C-1. In some embodiments, the second bonding layer 130 described in FIG. 9 of the package structure PK1 may be formed on the semiconductor wafer WF1. For example, the second bonding pads 130A are electrically connected to the conductive vias 140C-2 of the second semiconductor dies 140 of the semiconductor wafer WF1. In some embodiments, the second bonding layer 130 is formed on the semiconductor wafer WF1 so that it extends from the die regions DR1 towards the scribe line regions SL1. In certain embodiments, sidewalls of second bonding layer 130 are formed to be aligned with sidewalls of the semiconductor wafer WF1.

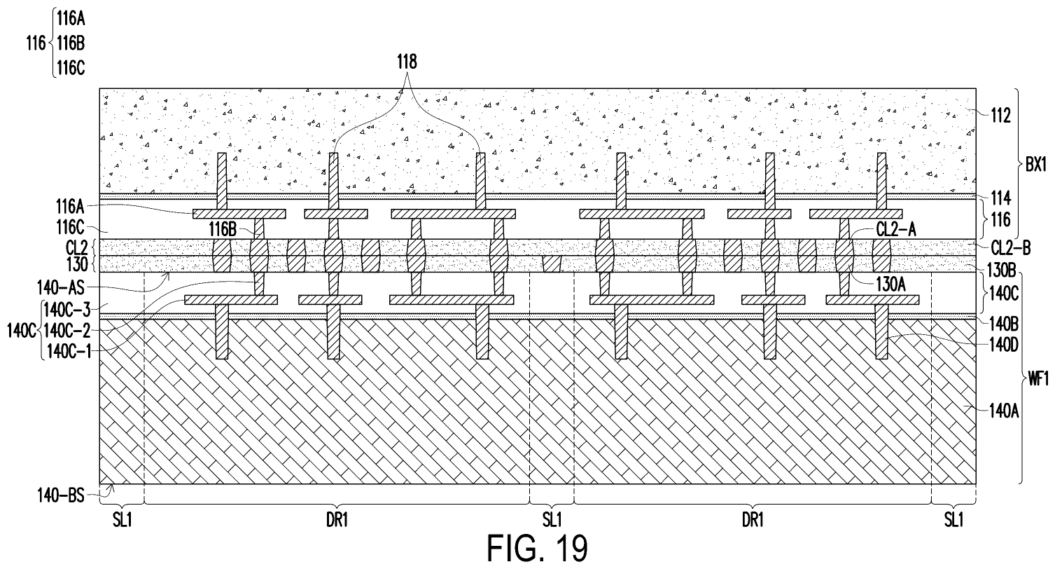

Referring to FIG. 19, in a subsequent step, a bridge layer BX1 (or interposer structure) is bonded to the second bonding layer 130 through a second connection layer CL2. For example, the second connection layer CL2 is first formed on a surface of the bridge layer BX1 so that the second connection layer CL2 can be bonded to the second bonding layer 130 along with the bridge layer BX1. As illustrated in FIG. 19, the connection pads CL2-A of the second connection layer CL2 are physically and electrically connected to the second bonding pads 130A, while the conductive lines 116A and/or the conductive vias 116B of the interconnection layer 116 of the bridge layer BX1 is electrically connected to the connection pads CL2-A.

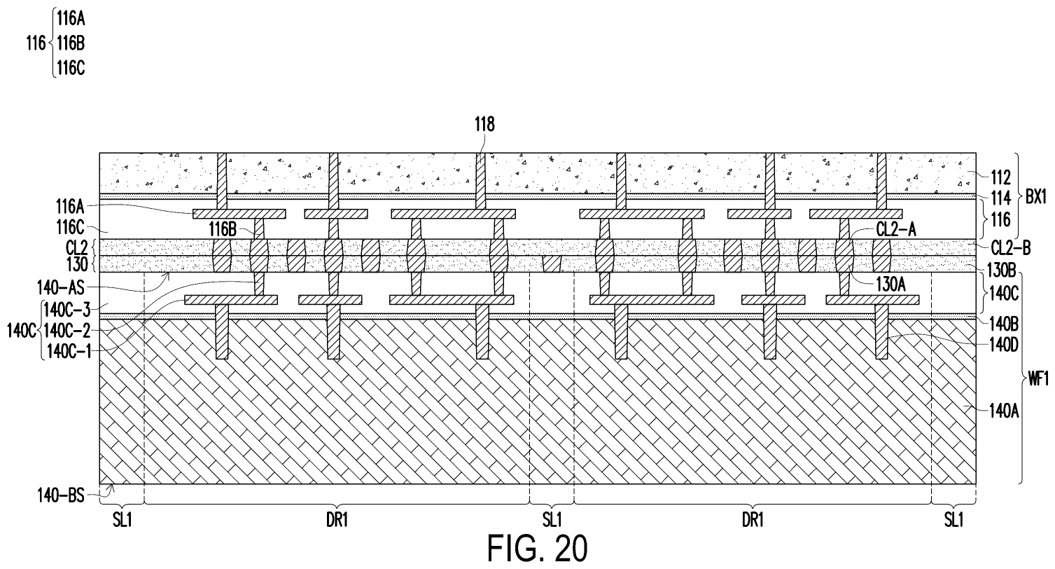

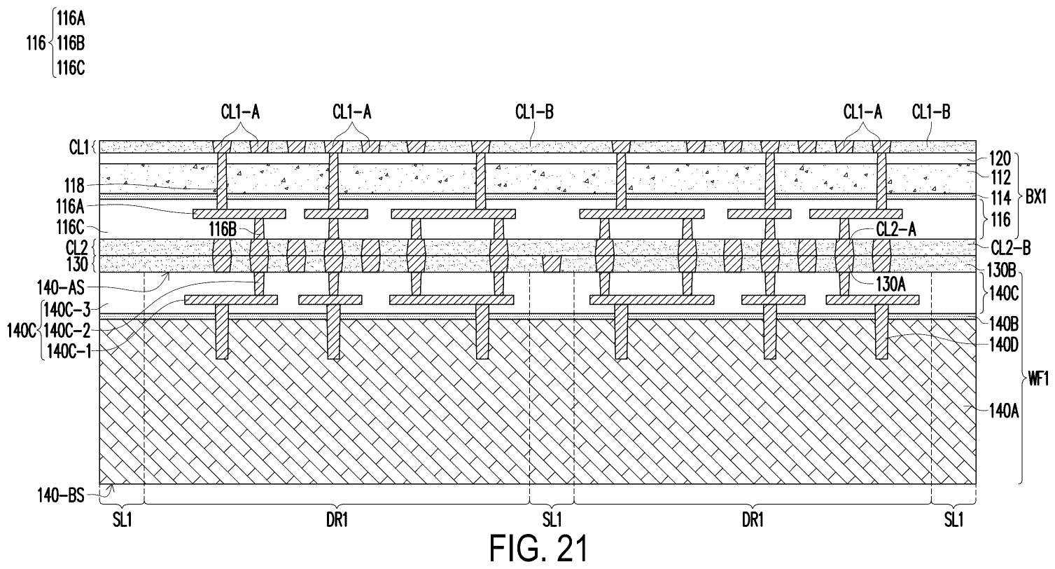

Referring to FIG. 20, after bonding the bridge layer BX1 onto the second bonding layer 130, the substrate structure 112 is thinned down to reveal the through vias 118. As illustrated in FIG. 21, the substrate structure 112 may be further recessed, for example through an etching process, so that the through vias 118 are protruding out from the substrate structure 112. Thereafter, a passivation layer 120 is formed on the substrate structure 112 to laterally surround the through vias 118. In some embodiments, a first connection layer CL1 is formed on the bridge layer BX1 and on the passivation layer 120. For example, the connection pads CL1-A are physically and electrically connected to the through vias 118 of the bridge layer BX1.

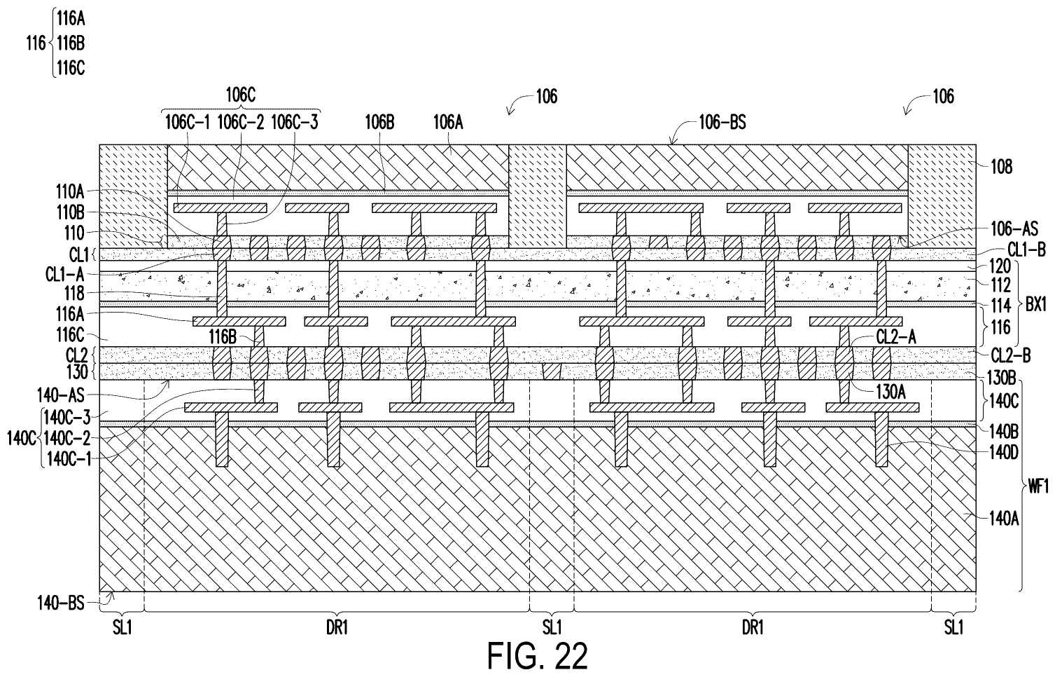

Referring to FIG. 22, in a subsequent step, a plurality of first semiconductor dies 106 is bonded to the first connection layer CL1 through a first bonding layer 110. For example, the first bonding layer 110 is first formed on an active surface 106-AS of the first semiconductor dies 110 so that the first bonding layer 110 can be bonded to the first connection layer CL1 along with the first semiconductor dies 106. In some embodiments, the first semiconductor dies 106 and the first bonding layer 110 are placed over the first connection layer CL1 by, e.g., a pick-and-place process. In some embodiments, forming the first bonding layer 110 includes forming a plurality of first bonding pads 110A disposed on and electrically connected to the first semiconductor dies 106, and forming a dielectric layer 110B surrounding the first bonding pads 110A.

As further illustrated in FIG. 22, the first semiconductor dies 106 are bonded onto the first connection layer CL1 so that the active surface 106-AS is facing the active surface 140-AS of the second semiconductor dies 140. In other words, the first semiconductor dies 106 and the second semiconductor dies 140 are arranged in a face-to-face manner. After bonding the first semiconductor dies 106, an insulating encapsulant 108 (or molding compound) is formed to encapsulate the first semiconductor dies 106. In some embodiments, portions of the insulating encapsulant 108 and portions of the backside surfaces 106-BS of the first semiconductor dies 106 are removed. For example, the insulating encapsulant 108 and the backside surfaces 106-BS of the first semiconductor dies 106 are ground or polished by a planarization step, such as a mechanical grinding process and/or a chemical mechanical polishing (CMP) process. After the planarization step, the backside surfaces 106-BS of the first semiconductor dies 106 and a surface of the insulating encapsulant 108 are coplanar and levelled with one another.

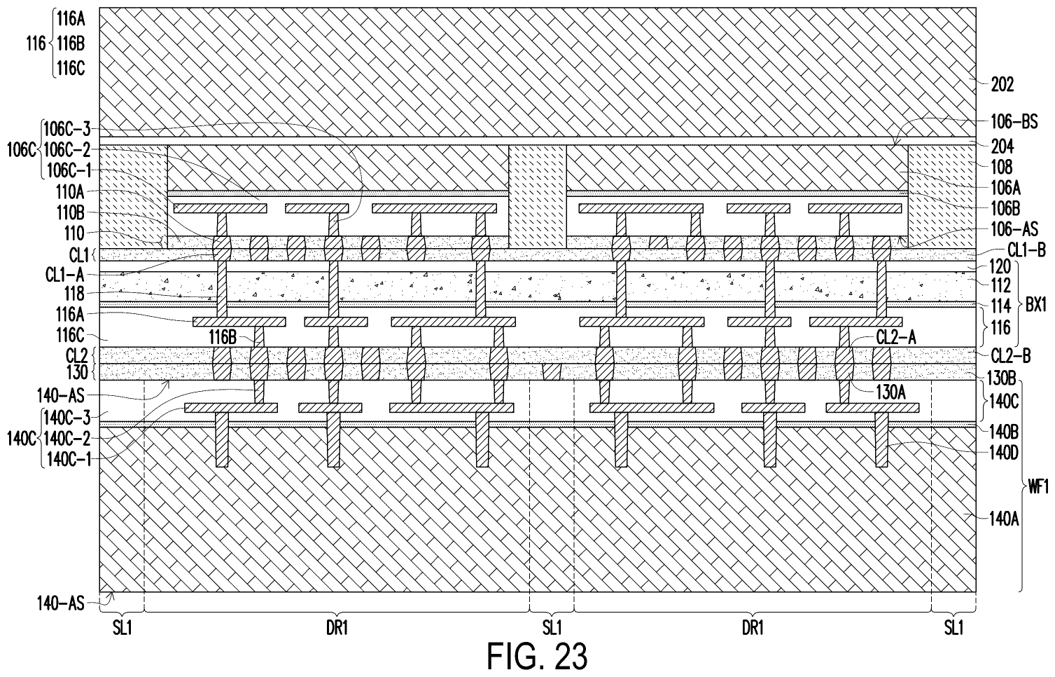

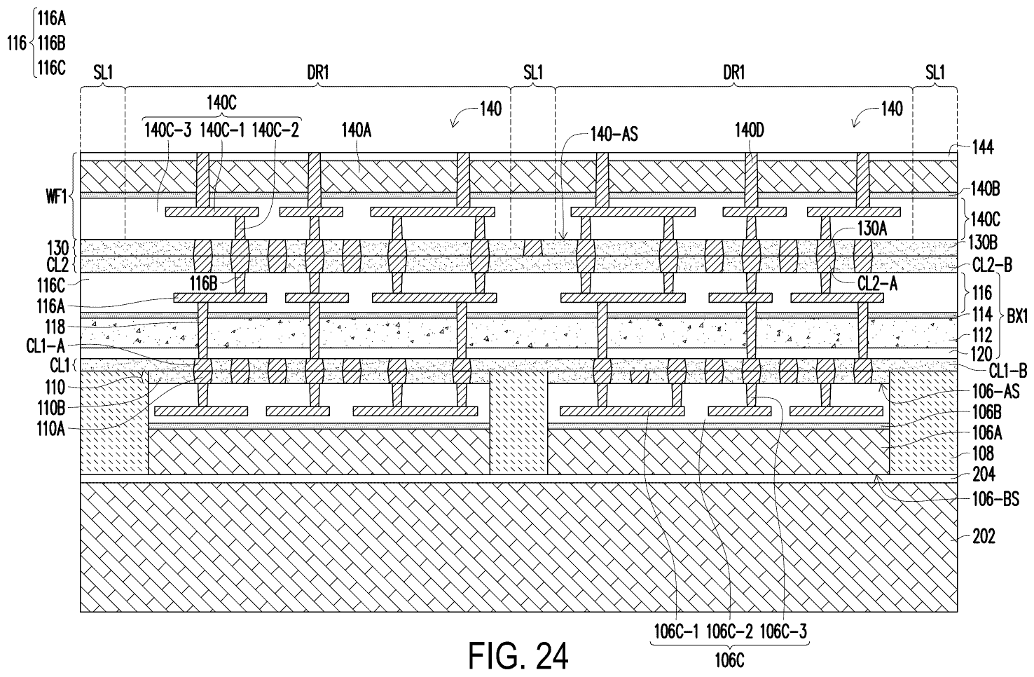

Referring to FIG. 23, in a subsequent step, a second carrier 202 is bonded to the backside surfaces 106-BS of the first semiconductor dies 106 through a buffer layer 204. Thereafter, as illustrated in FIG. 24, the structure shown in FIG. 23 is flipped around, and the semiconductor wafer WF1 is thinned down to reveal the backside vias 140D. In some embodiments, the semiconductor substrate 140A is thinned down, and further recessed, so that the backside vias 140D are protruding out from the semiconductor substrate 140A. Subsequently, a passivation layer 144 is formed on the semiconductor substrate 140A to laterally surround the backside vias 140D.

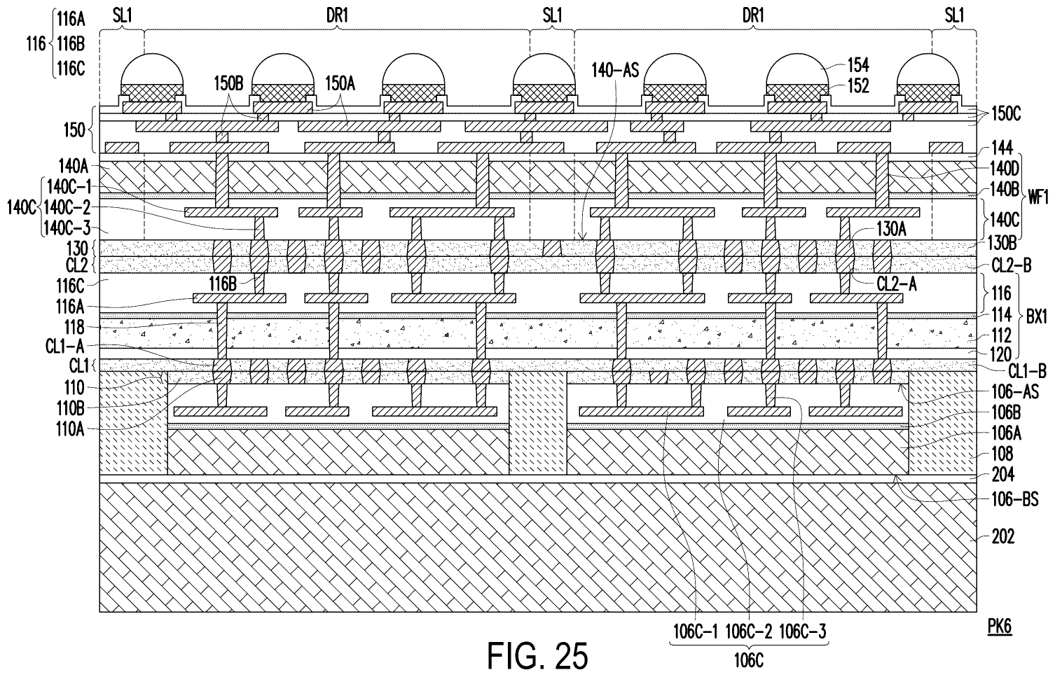

Referring to FIG. 25, after forming the passivation layer 144, a redistribution layer 150 is formed on the backside surfaces 140-BS of the second semiconductor dies 140. For example, the redistribution layer 150 is physically and electrically connected to the backside vias 140D of the second semiconductor dies 140. After forming the redistribution layer 150, a plurality of conductive pads 152 are disposed on an exposed top surface of the topmost layer of the metal lines 150A for electrically connecting with conductive terminals. After forming the conductive pads 152, a plurality of conductive terminals 154 is disposed on the conductive pads 152 and over the redistribution layer 150. After forming the conductive pads 152 and conductive terminals 154, multiple semiconductor packages PK6 including the above package components are formed on the same carrier substrate(s) and then singulated to form individual semiconductor package PK6.

In the semiconductor package PK6, sidewalls of the semiconductor wafer WF1 (including the second semiconductor dies 140) are aligned with sidewalls of the bridge layer BX1, and aligned with sidewalls of the insulating encapsulant 108. Furthermore, since a bridge layer BX1 is provided between the first semiconductor dies 106 and the semiconductor wafer WF1 (including the second semiconductor dies 140), die to die signals can be transferred both horizontally and vertically, allowing multiple data transferring path between die-to-die areas for signal communication. As such, with the additional signal transferring paths, the semiconductor package PK6 can be used for super powerful data processing.

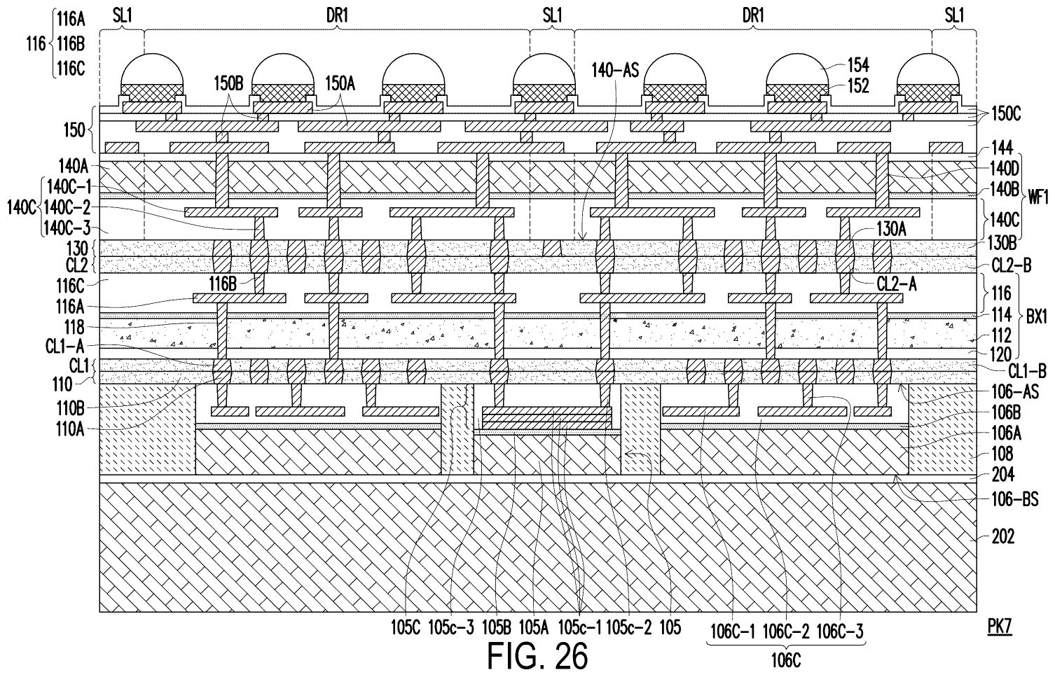

FIG. 26 is a schematic sectional view of a semiconductor package according to some other exemplary embodiments of the present disclosure. The semiconductor package PK7 illustrated in FIG. 26 is similar to the semiconductor package PK6 illustrated in FIG. 25. Therefore, the same reference numerals are used to refer to the same or like parts, and its detailed description are omitted herein. The difference between the semiconductor package PK6 of FIG. 25 and the semiconductor package PK7 of FIG. 26 is that a bridge die 105 is further provided in the semiconductor package PK7.

As illustrated in FIG. 26, the bridge die 105 is embedded in the insulating encapsulant 108, and is located aside the first semiconductor dies 106, and electrically connected to the bridge layer BX1 through the first bonding layer 110 and the first connection layer CL1. In certain embodiments, the bridge die 105 is further electrically connecting the plurality of second semiconductor dies 140 to one another. The bridge die 105 illustrated herein is similar to the bridge die 105 described in FIG. 13, thus its detailed description will be omitted herein. In the semiconductor package PK7, since a bridge layer BX1 is provided between the first semiconductor dies 106 and the semiconductor wafer WF1 (including the second semiconductor dies 140), and a bridge die 105 is further provided for interconnection, die to die signals can be transferred both horizontally and vertically, allowing multiple data transferring path between die-to-die areas for signal communication. As such, with the additional signal transferring paths, the semiconductor package PK7 can be used for super powerful data processing.

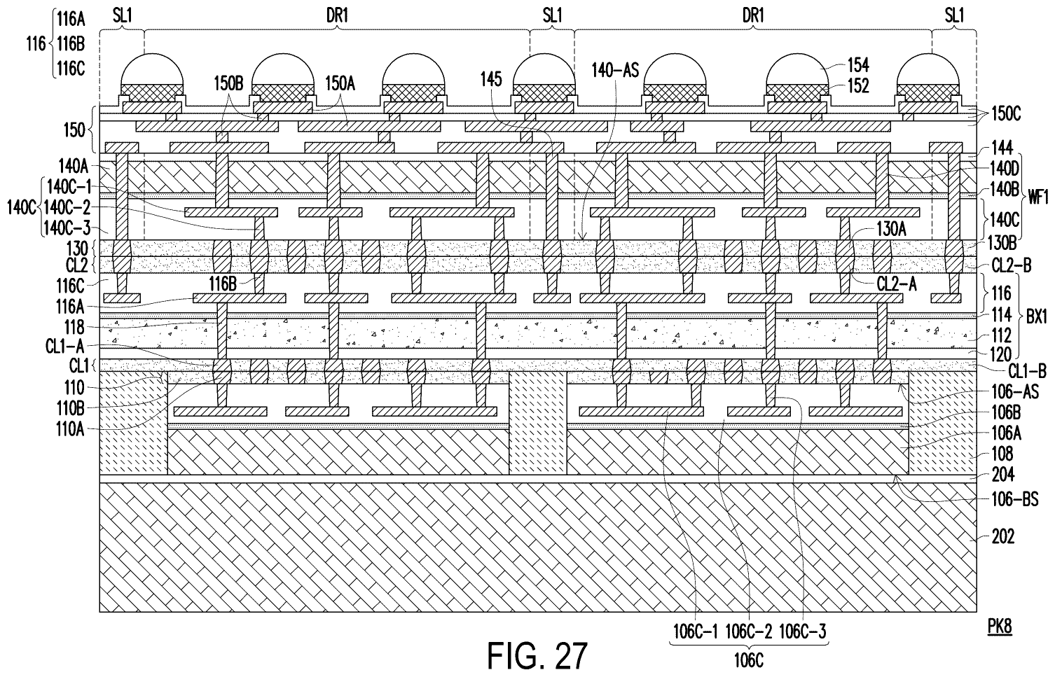

FIG. 27 is a schematic sectional view of a semiconductor package according to some other exemplary embodiments of the present disclosure. The semiconductor package P8 illustrated in FIG. 27 is similar to the semiconductor package PK6 illustrated in FIG. 25. Therefore, the same reference numerals are used to refer to the same or like parts, and its detailed description are omitted herein. The difference between the semiconductor package PK6 of FIG. 25 and the semiconductor package PK8 of FIG. 27 is that through dielectric vias 145 are further formed in the semiconductor package PK8.

As illustrated in FIG. 27, in some embodiments, through dielectric vias 145 are formed in the scribe line regions SL1 of the semiconductor wafer WF1. In some embodiments, the through dielectric vias 145 are surrounding the second semiconductor dies 140 in the die regions DR1 and separating the plurality of second semiconductor dies 140 from one another. Furthermore, the through dielectric vias 145 may be electrically connecting the bridge layer BX1 (or interposer structure) to the redistribution layer 150. For example, the through dielectric vias 145 are electrically connected to the bridge layer BX1 through the second bonding layer 130 and the second connection layer CL2. In the semiconductor package PK8, since a bridge layer BX1 is provided between the first semiconductor dies 106 and the semiconductor wafer WF1 (including the second semiconductor dies 140), and the through dielectric vias 145 are further provided for vertical interconnection, die to die signals can be transferred both horizontally and vertically, allowing multiple data transferring path between die-to-die areas for signal communication. As such, with the additional signal transferring paths, the semiconductor package PK8 can be used for super powerful data processing.

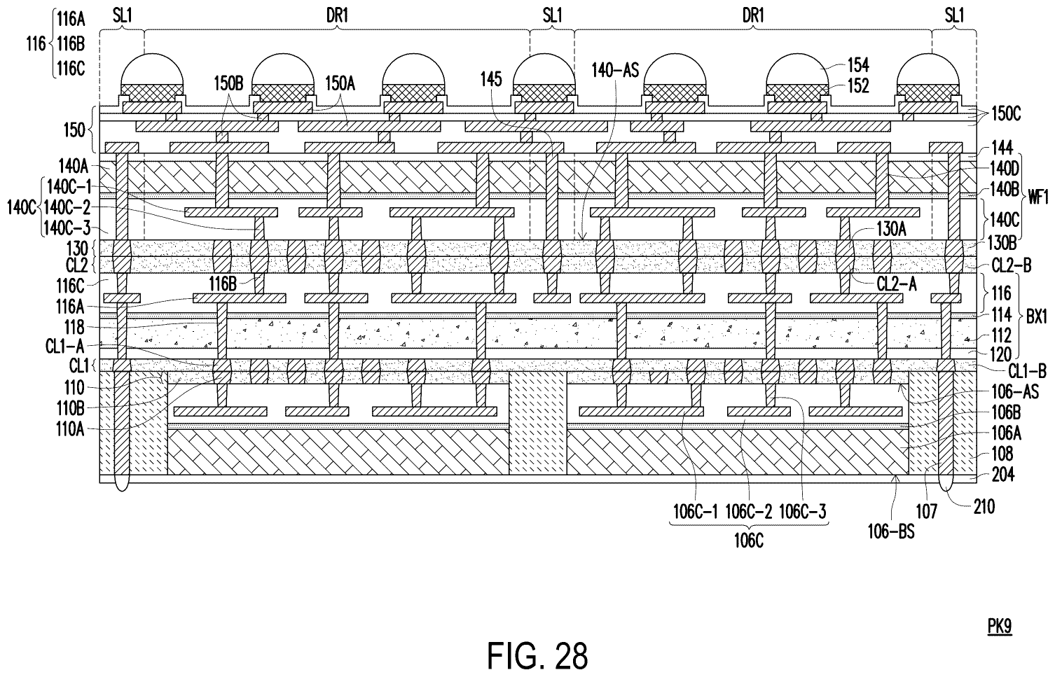

FIG. 28 is a schematic sectional view of a semiconductor package according to some other exemplary embodiments of the present disclosure. The semiconductor package PK9 illustrated in FIG. 28 is similar to the semiconductor package PK8 illustrated in FIG. 27. Therefore, the same reference numerals are used to refer to the same or like parts, and its detailed description are omitted herein.

As illustrated in FIG. 28, in some embodiments, a plurality of through dielectric vias 107 are further formed in the insulating encapsulant 108 to surround the first semiconductor dies 106. In some embodiments, the second carrier 202 shown in the semiconductor package PK8 of FIG. 27 is debonded from the package structure PK9 of FIG. 28. As shown in FIG. 28, the buffer layer 204 (or dielectric layer 204B) is patterned to form a plurality of openings revealing the through dielectric vias 107. Thereafter, a plurality of conductive terminals 210 are, for example, reflowed to bond with the bottom surfaces of the through dielectric vias 107. After the conductive terminals 210 are formed, a semiconductor package PK9 having dual-side terminals is accomplished.

In the semiconductor package PK9, since a bridge layer BX1 is provided between the first semiconductor dies 106 and the semiconductor wafer WF1 (including the second semiconductor dies 140), and the through dielectric vias 145, 107 are further provided for vertical interconnection, die to die signals can be transferred both horizontally and vertically, allowing multiple data transferring path between die-to-die areas for signal communication. As such, with the additional signal transferring paths, the semiconductor package PK9 can be used for super powerful data processing.

In the above-mentioned embodiments, the semiconductor package at least includes a bridge layer for providing multiple interconnecting selection between the first and second semiconductor dies, which allows the transfer of die to die signals both horizontally and vertically. As such, with the arrangement of the bridge layer for providing additional paths for signal communication, the semiconductor package can be used for super powerful data processing.

In accordance with some embodiments of the present disclosure, a semiconductor package includes a plurality of first semiconductor dies, a plurality of first bonding pads, a bridge layer, a plurality of second bonding pads and a plurality of second semiconductor dies. The first bonding pads are disposed on the first semiconductor dies. The bridge layer is disposed on the first bonding pads, wherein the bridge layer is electrically connected to the first semiconductor dies through the first bonding pads. The second bonding pads are disposed on the bridge layer, wherein the second bonding pads are electrically connected to the first bonding pads through the bridge layer. The second semiconductor dies are disposed on and electrically connected to the second bonding pads, wherein an active surface of the first semiconductor dies is facing an active surface of the second semiconductor dies.

In accordance with some other embodiments of the present disclosure, a semiconductor package includes a first insulating encapsulant, a plurality of first semiconductor dies, a plurality of second semiconductor dies, an interposer structure and a redistribution layer. The first semiconductor dies are embedded in the first insulating encapsulant. The second semiconductor dies are located over the first semiconductor dies. The interposer structure is disposed in between and electrically connecting the first semiconductor dies to the second semiconductor dies. The redistribution layer is disposed on and electrically connected to the second semiconductor dies, wherein sidewalls of the redistribution layer are aligned with sidewalls of the interposer structure and sidewalls of the first insulating encapsulant.

In accordance with yet another embodiment of the present disclosure, a method of fabricating a semiconductor package is described. The method includes: placing a plurality of first semiconductor dies on a carrier; forming a plurality of first bonding pads on the first semiconductor dies; placing a bridge layer on the first bonding pads, wherein the bridge layer is electrically connected to the first semiconductor dies through the first bonding pads; forming a plurality of second bonding pads on the bridge layer, wherein the second bonding pads are electrically connected to the first bonding pads through the bridge layer; and placing a plurality of second semiconductor dies on the second bonding pads, and electrically connecting the second semiconductor dies to the second bonding pads, wherein an active surface of the first semiconductor dies is facing an active surface of the second semiconductor dies.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a plurality of first semiconductor dies;
a plurality of first bonding pads disposed on the plurality of first semiconductor dies;
a bridge layer disposed on the plurality of first bonding pads, wherein the bridge layer is electrically connected to the plurality of first semiconductor dies through the plurality of first bonding pads;
a plurality of second bonding pads disposed on the bridge layer, wherein the plurality of second bonding pads is electrically connected to the plurality of first bonding pads through the bridge layer; and
a plurality of second semiconductor dies disposed on and electrically connected to the plurality of second bonding pads, wherein an active surface of the plurality of first semiconductor dies is facing an active surface of the plurality of second semiconductor dies.

2. The semiconductor package according to claim 1, wherein the bridge layer comprises:
a substrate structure;
through vias extending across the substrate structure; and
an interconnection layer disposed on the substrate structure and electrically connected to the through vias, wherein the plurality of first bonding pads is electrically connected to the interconnection layer, and the plurality of second bonding pads is electrically connected to the through vias.

3. The semiconductor package according to claim 1, further comprising:
a first connection layer disposed in between the bridge layer and the plurality of first bonding pads, wherein the first connection layer comprises a plurality of first connection pads electrically connected to the bridge layer and the plurality of first bonding pads; and
a second connection layer disposed in between the bridge layer and the plurality of second bonding pads, wherein the second connection layer comprises a plurality of second connection pads electrically connected to the bridge layer and the plurality of second bonding pads.

4. The semiconductor package according to claim 1,
a redistribution layer disposed on backside surfaces of the plurality of second semiconductor dies; and
a plurality of conductive terminals disposed on and electrically connected to the redistribution layer.

5. The semiconductor package according to claim 4, wherein each of the plurality of second semiconductor dies comprises:
a die substrate;
an die interconnection layer disposed on the die substrate;
conductive vias disposed in the die interconnection layer and electrically connected to the plurality of second bonding pads; and
backside vias extending across the die substrate and electrically connecting the die interconnection layer to the redistribution layer.

6. The semiconductor package according to claim 1, wherein the plurality of second semiconductor dies are parts of a semiconductor wafer, and the semiconductor wafer comprises die regions including the plurality of second semiconductor dies, and scribe line regions joining the plurality of second semiconductor dies together, and wherein sidewalls of the semiconductor wafer are aligned with sidewalls of the bridge layer.

7. The semiconductor package according to claim 1, further comprising:
a plurality of through dielectric vias separating the plurality of second semiconductor dies and electrically connected to the bridge layer.

8. The semiconductor package according to claim 1, further comprising:
a bridge die located in between the plurality of first semiconductor dies, and electrically connected to the plurality of second semiconductor dies through the plurality of first bonding pads, the bridge layer and the plurality of second bonding pads.

9. A semiconductor package, comprising:
a first insulating encapsulant;
a plurality of first semiconductor dies embedded in the first insulating encapsulant;
a plurality of second semiconductor dies located over the plurality of first semiconductor dies;
an interposer structure disposed in between and electrically connecting the plurality of first semiconductor dies to the plurality of second semiconductor dies; and
a redistribution layer disposed on and electrically connected to the plurality of second semiconductor dies, wherein sidewalls of the redistribution layer are aligned with sidewalls of the interposer structure and sidewalls of the first insulating encapsulant.

10. The semiconductor package according to claim 9, wherein the interposer structure comprises:
a substrate structure;
through vias extending across the substrate structure; and
an interconnection layer disposed on the substrate structure and electrically connected to the through vias, wherein the plurality of first semiconductor dies is electrically connected to the plurality of second semiconductor dies through the interconnection layer and the through vias.

11. The semiconductor package according to claim 10, further comprising a passivation layer disposed on the substrate structure and laterally surrounding the through vias.

12. The semiconductor package according to claim 9, further comprising:
a first connection layer disposed on a first surface of the interposer structure and electrically connecting the interposer structure to the plurality of first semiconductor dies; and
a second connection layer disposed on a second surface of the interposer structure and electrically connecting the interposer structure to the plurality of second semiconductor dies, wherein the second surface is opposite to the first surface.

13. The semiconductor package according to claim 9, further comprising:
a second insulating encapsulant surrounding the plurality of second semiconductor dies, wherein sidewalls of the second insulating encapsulant are aligned with the sidewalls of the interposer structure and the sidewalls of the first insulating encapsulant.

14. The semiconductor package according to claim 13, further comprising a plurality of through dielectric vias embedded in the second insulating encapsulant and surrounding the plurality of second semiconductor dies, wherein the through dielectric vias are electrically connecting the interposer structure to the redistribution layer.

15. The semiconductor package according to claim 9, wherein the plurality of second semiconductor dies are parts of a semiconductor wafer, and the semiconductor wafer comprises die regions including the plurality of second semiconductor dies, and scribe line regions joining the plurality of second semiconductor dies together, and wherein sidewalls of the semiconductor wafer are aligned with the sidewalls of the interposer structure and the sidewalls of the first insulating encapsulant.

16. A method of fabricating a semiconductor package, comprising:
placing a plurality of first semiconductor dies on a carrier;
forming a plurality of first bonding pads on the plurality of first semiconductor dies;
placing a bridge layer on the plurality of first bonding pads, wherein the bridge layer is electrically connected to the plurality of first semiconductor dies through the plurality of first bonding pads;
forming a plurality of second bonding pads on the bridge layer, wherein the plurality of second bonding pads is electrically connected to the plurality of first bonding pads through the bridge layer; and
placing a plurality of second semiconductor dies on the plurality of second bonding pads, and electrically connecting the plurality of second semiconductor dies to the plurality of second bonding pads, wherein an active surface of the plurality of first semiconductor dies is facing an active surface of the plurality of second semiconductor dies.

17. The method according to claim 16, wherein the bridge layer comprises:
a substrate structure;
through vias embedded in the substrate structure; and
an interconnection layer disposed on the substrate structure and electrically connected to the through vias,
wherein after placing the bridge layer on the plurality of first bonding pads, the method further comprises thinning down the substrate structure to reveal the through vias so that the through vias are extending across the substrate structure, and after forming the plurality of second bonding pads on the bridge layer, the plurality of second bonding pads is electrically connected to the through vias.

18. The method according to claim 16, further comprising:
forming a first connection layer disposed on and electrically connected to the plurality of first bonding pads;
placing the bridge layer on the first connection layer over the plurality of first bonding pads;
forming a second connection layer disposed on and electrically connected to the bridge layer; and
forming the plurality of second bonding pads on second connection layer over the bridge layer.

19. The method according to claim 16, further comprising:
forming a redistribution layer on backside surfaces of the plurality of second semiconductor dies; and
forming a plurality of conductive terminals disposed on and electrically connected to the redistribution layer.

20. The method according to claim 16, further comprising:
forming a plurality of through dielectric vias aside the plurality of second semiconductor dies, wherein the plurality of through dielectric vias is electrically connected to the bridge layer.
